(19) United States
(12) Patent Application Publication
(10) Pub. No.: US 2025/0040136 A1
(43) Pub. Date: Jan. 30, 2025

(54) SEMICONDUCTOR MEMORY

(71) Applicant: SK hynix Inc., Icheon-si Gyeonggi-do (KR)

(72) Inventor: In Ku KANG, Icheon-si Gyeonggi-do (KR)

(73) Assignee: SK hynix Inc., Icheon-si Gyeonggi-do (KR)

(21) Appl. No.: 18/397,551

(22) Filed: Dec. 27, 2023

(30) Foreign Application Priority Data
Jul. 24, 2023 (KR) 10-2023-0096145

(51) Int. Cl. H10B 43/27; G11C 16/04; H10B 41/10; H10B 41/27; H10B 43/10

(52) U.S. Cl. CPC H10B 43/27; G11C 16/0483; H10B 41/10; H10B 41/27; H10B 43/10

(57) ABSTRACT

There are provided a semiconductor memory device and a method of manufacturing the semiconductor memory device. The semiconductor memory device includes a lower interlayer insulating layer, an upper interlayer insulating layer, a channel pattern passing through the lower interlayer insulating layer and the upper interlayer insulating layer, a conductive layer facing the channel pattern between the lower interlayer insulating layer and the upper interlayer insulating layer, and a storage pattern arranged in a lateral groove, the lateral groove defined between the conductive layer and the channel pattern by the lower interlayer insulating layer and the upper interlayer insulating layer protruding toward the channel pattern more than the conducive layer, in which a distance from the conductive layer from the channel pattern decreases toward an end of the lateral groove.

### CROSS-REFERENCE TO RELATED APPLICATION

The present application claims priority under 35 U.S.C. § 119 (a) to Korean patent application number 10-2023-0096145 filed on Jul. 24, 2023, in the Korean Intellectual Property Office, the entire disclosure of which is incorporated by reference herein.

### BACKGROUND

### 1. Technical Field

Various embodiments of the present disclosure relate generally to an electronic device and a method of manufacturing the electronic device, and more particularly, to a semiconductor memory device and a method of manufacturing the semiconductor memory device.

### 2. Related Art

Semiconductor memory devices are applied to electronic devices in various fields such as automobiles, medical care, and data centers, as well as small electronic devices. Accordingly, the demand for semiconductor memory devices has been increasing.

A semiconductor memory device may include a memory cell for storing data. Three-dimensional semiconductor memory devices have been proposed to achieve large-capacity semiconductor memory devices. A three-dimensional semiconductor memory device may include a plurality of memory cells which are arranged in three dimensions.

### SUMMARY

According to an embodiment, a semiconductor memory device may include a lower interlayer insulating layer overlapping a center line, the center line extending in a plane parallel to the lower interlayer insulating layer, an upper interlayer insulating layer spaced apart from the lower interlayer insulating layer in a direction crossing the plane, a first channel pattern and a second channel pattern extending to pass through the lower interlayer insulating layer and the upper interlayer insulating layer, the first channel pattern spaced apart from the second channel pattern, and the center line interposed between the first and second channel patterns, a conductive layer arranged between the lower interlayer insulating layer and the upper interlayer insulating layer, the conductive layer including a first area facing the first channel pattern, a second area facing the second channel pattern, and a third area coupling the first area to the second area, and a first data storage pattern formed in a first lateral groove, the first lateral groove defined between the conductive layer and the first channel pattern by the lower interlayer insulating layer and the upper interlayer insulating layer, the upper and lower insulating layers protruding toward the first channel pattern more than the conductive layer, wherein a variable width of the first lateral groove in the plane decreases toward an end of the first lateral groove.

According to an embodiment, a semiconductor memory device may include a first lower interlayer insulating pattern and a second lower interlayer insulating pattern spaced apart from each other with a center line interposed therebetween, the center line extending in a direction in a plane parallel to the each of the first and second lower interlayer insulating patterns, a first upper interlayer insulating pattern spaced apart from the first lower interlayer insulating pattern in a direction crossing the plane, a second upper interlayer insulating pattern spaced apart from the second lower interlayer insulating pattern in the direction crossing the plane, a first channel pattern and a second channel pattern extending to pass from between the first lower interlayer insulating pattern and the second lower interlayer insulating pattern to between the first upper interlayer insulating pattern and the second upper interlayer insulating pattern, the first channel pattern and the second channel pattern spaced apart from each other with the center line interposed therebetween, a first conductive pattern arranged between the first lower interlayer insulating pattern and the first upper interlayer insulating pattern, a second conductive pattern arranged between the second lower interlayer insulating pattern and the second upper interlayer insulating pattern, and a first data storage pattern formed in a first lateral groove, the first lateral groove defined between the first conductive pattern and the first channel pattern by the first lower interlayer insulating pattern and the first upper interlayer insulating pattern, the first lower interlayer insulating pattern and the first upper interlayer insulating pattern each protruding toward the first channel pattern more than the first conductive pattern, wherein a variable width of the first lateral groove in the plane decreases toward an end of the first lateral groove.

According to an embodiment, a semiconductor memory device may include a first lower interlayer insulating pattern and a second lower interlayer insulating pattern spaced apart from each other with a center line interposed therebetween, the center line extending in a direction in a plane parallel to each of the first and second lower interlayer insulating patterns, a first upper interlayer insulating pattern spaced apart from the first lower interlayer insulating pattern in a direction crossing the plane, a second upper interlayer insulating pattern spaced apart from the second lower interlayer insulating pattern in the direction crossing the plane, a channel layer extending to pass from between the first lower interlayer insulating pattern and the second lower interlayer insulating pattern to between the first upper interlayer insulating pattern and the second upper interlayer insulating pattern, a first conductive pattern arranged between the first lower interlayer insulating pattern and the first upper interlayer insulating pattern, a second conductive pattern arranged between the second lower interlayer insulating pattern and the second upper interlayer insulating pattern, and a first data storage pattern formed in a first lateral groove, the first lateral groove defined between the first conductive pattern and the channel layer by the first lower interlayer insulating pattern and the first upper interlayer insulating pattern, the first lower interlayer insulating pattern and the first upper interlayer insulating pattern each protruding toward the channel layer more than the first conductive pattern, wherein a variable width of the first lateral groove in the plane decreases toward an end of the first data storage pattern.

According to an embodiment, a method of manufacturing a semiconductor memory device may include forming a preliminary stack structure including a plurality of first material layers and a plurality of second material layers stacked alternately with each other, forming a hole passing through the plurality of first material layers and the plurality of second material layers, the hole including a major axis in a first direction and a minor axis in a second direction crossing the major axis in a plane, forming a first etch barrier pattern extending along a first inner wall of the hole and a second etch barrier pattern extending along a second inner wall of the hole, the first inner wall and the second inner wall opposing each other in the first direction in the hole, the first etch barrier pattern and the second etch barrier pattern blocking the plurality of first material layers and the plurality of second material layers, forming a first lateral groove and a second lateral groove adjacent to each other in the second direction between two first material layers adjacent to each other in a stacking direction, among the plurality of first material layers, by etching the plurality of second material layers exposed through a third inner wall and a fourth inner wall facing each other in the second direction in the hole, and forming a first data storage pattern in the first lateral groove and a second data storage pattern in the second lateral groove.

### BRIEF DESCRIPTION OF THE DRAWINGS

FIG. 1 is a block diagram illustrating a semiconductor memory device according to an embodiment of the present disclosure;

FIG. 2 is a circuit diagram illustrating a memory cell array according to an embodiment of the present disclosure;

FIGS. 3A and 3B are diagrams illustrating vertical arrangement of a semiconductor memory device according to embodiments of the present disclosure;

FIGS. 4, 5A, 5B, 5C, 6A, and 6B are diagrams illustrating a semiconductor memory device according to an embodiment of the present disclosure;

FIGS. 7, 8A, and 8B are diagrams illustrating a semiconductor memory device according to an embodiment of the present disclosure;

FIGS. 9A and 9B are diagrams illustrating a semiconductor memory device according to embodiments of the present disclosure;

FIGS. 10, 11A, and 11B are diagrams illustrating a semiconductor memory device shown in FIG. 9A or 9B;

FIGS. 12, 13A, and 13B are diagrams illustrating a semiconductor memory device according to an embodiment of the present disclosure;

FIGS. 14, 15A, and 15B are diagrams illustrating a semiconductor memory device according to an embodiment of the present disclosure;

FIGS. 16, 17, 18A, and 18B are diagrams illustrating a semiconductor memory device according to an embodiment of the present disclosure;

FIGS. 19, 20A, 20B, 21, 22A, 22B, 23, 24A, 24B, 25, 26A, 26B, 27, 28, 29, 30, 31, 32A, 32B, 33, 34A, 34B, 35A, and 35B are diagrams illustrating a method of manufacturing a semiconductor memory device according to an embodiment of the present disclosure;

FIGS. 36A and 36B are diagrams illustrating a method of manufacturing a semiconductor memory device according to embodiments of the present disclosure;

FIGS. 37A and 37B are diagrams illustrating a method of manufacturing a semiconductor memory device according to embodiments of the present disclosure;

FIGS. 38, 39A, 39B, 40, 41A, 41B, and 42 are diagrams illustrating a method of manufacturing a semiconductor memory device according to an embodiment of the present disclosure;

FIG. 43 is a plan view illustrating a method of manufacturing a semiconductor memory device according to an embodiment of the present disclosure;

FIGS. 44, 45A, 45B, 46, 47A, 47B, 48, 49A and 49B are diagrams illustrating a method of manufacturing a semiconductor memory device according to an embodiment of the present disclosure;

FIGS. 50, 51, 52, 53, 54, 55, 56 and 57 are diagrams illustrating a method of manufacturing a semiconductor memory device according to an embodiment of the present disclosure;

FIG. 58 is a plan view illustrating a method of manufacturing a semiconductor memory device according to an embodiment of the present disclosure; and

FIG. 59 is a block diagram illustrating an electronic system including a semiconductor memory device according to embodiments of the present disclosure.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Hereinafter, use of ordinal terms such as “first,” “second,” etc., in the claims to modify a claim element does not by itself connote any priority, precedence, or order of one claim element over another or the temporal order in which acts of a method are performed. Such terms are used merely as labels to distinguish one claim element having a certain name from another element having a same name (but for use of the ordinal term).

Various embodiments of the present disclosure are directed to a semiconductor memory device capable of improving operational reliability and a manufacturing method thereof.

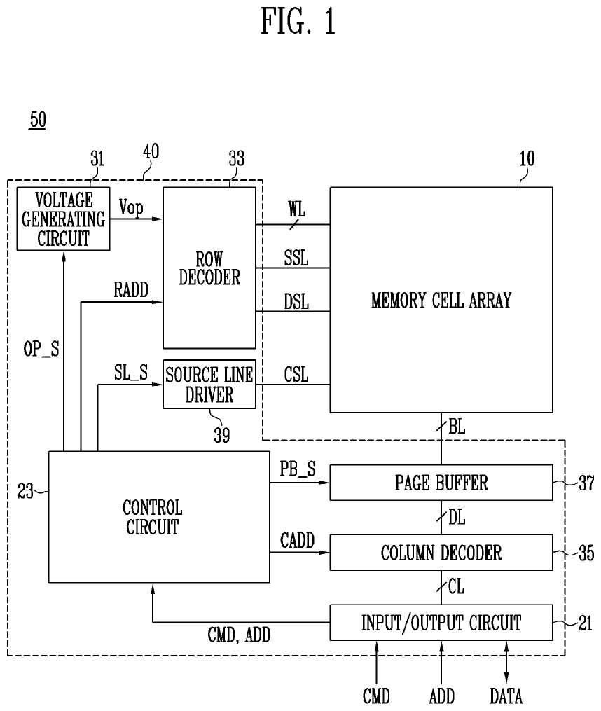

FIG. 1 is a block diagram illustrating a semiconductor memory device 50 according to an embodiment of the present disclosure.

Referring to FIG. 1, the semiconductor memory device 50 may include a peripheral circuit 40 and a memory cell array 10.

The peripheral circuit 40 may be configured to perform a program operation of storing data in the memory cell array 10, a read operation of outputting data stored in the memory cell array 10, and an erase operation of erasing data stored in the memory cell array 10. According to an embodiment, the peripheral circuit 40 may include an input/output circuit 21, a control circuit 23, a voltage generating circuit 31, a row decoder 33, a column decoder 35, a page buffer 37, and a source line driver 39.

The peripheral circuit 40 may be coupled to the memory cell array 10 through a common source line CSL, a bit line BL, a drain select line DSL, a word line WL, and a source select line SSL.

The input/output circuit 21 may transfer a command CMD and an address ADD, which are received from an external device (e.g., a memory controller) of the semiconductor memory device 50, to the control circuit 23. The input/output circuit 21 may exchange data DATA with the external device and the column decoder 35.

The control circuit 23 may output an operating signal OP_S, a row address RADD, a source line control signal SL_S, a page buffer control signal PB_S, and a column address CADD in response to the command CMD and the address ADD.

The voltage generating circuit 31 may generate various operating voltages Vop applied to perform a program operation, a read operation, and an erase operation.

The row decoder 33 may transfer the operating voltages Vop to the drain select line DSL, the word line WL, and the source select line SSL in response to the row address RADD.

The column decoder 35 may transfer the data DATA, which is input from the input/output circuit 21, to the page buffer 37, or may transfer the data DATA stored in the page buffer 37 to the input/output circuit 21 in response to the column address CADD. The column decoder 35 may exchange the data DATA with the input/output circuit 21 through a column line CL. The column decoder 35 may exchange the data DATA with the page buffer 37 through a data line DL.

The page buffer 37 may store read data received through the bit line BL in response to the page buffer control signal PB_S. The page buffer 37 may sense voltages or currents in the bit line BL during a read operation.

The source line driver 39 may control a voltage applied to the common source line CSL in response to the source line control signal SL_S.

The memory cell array 10 may include a plurality of memory blocks. Each of the memory blocks may include a plurality of memory cells which are arranged in three dimensions. The plurality of memory cells may be grouped into a plurality of memory cell strings. Each memory cell may be a non-volatile memory cell. According to an embodiment, each memory cell may be a NAND flash memory cell.

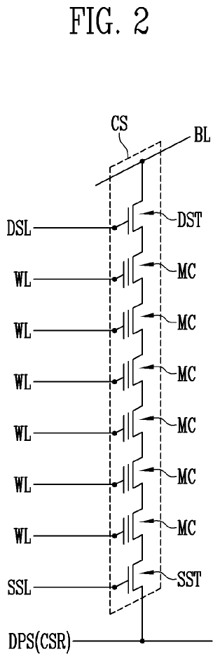

FIG. 2 is a circuit diagram illustrating a memory cell array according to an embodiment of the present disclosure.

Referring to FIG. 2, the memory cell array may include a memory cell string CS. The memory cell string CS may include at least one source select transistor SST, a plurality of memory cells MC, and at least one drain select transistor DST. The plurality of memory cells MC may be coupled in series between the source select transistor SST and the drain select transistor DST. The source select transistor SST, the plurality of memory cells MC, and the drain select transistor DST may be coupled in series by a channel pattern or a channel layer. The channel pattern or the channel layer may serve as a channel region of the memory cell string CS and include a semiconductor layer.

A common source region CSR and the bit line BL may be connected to the channel pattern or the channel layer of the memory cell string CS. A voltage for discharging a potential of the channel region potential of the memory cell string CS may be applied to the common source region CSR. A voltage for precharging the channel region of the memory cell string CS may be applied to the bit line BL.

The plurality of memory cells MC of the memory cell string CS may be connected to the common source region CSR through the source select transistor SST. The plurality of memory cells MC of the memory cell string CS may be connected to the bit line BL through the drain select transistor DST.

Gate electrodes of the source select transistor SST, the plurality of memory cells MC, and the drain select transistor DST may form a gate stack structure. The gate stack structure may include a source select line SSL provided as a gate electrode of the source select transistor SST, a plurality of word lines WL provided as a plurality of gate electrodes of the plurality of memory cells MC, and the drain select line DSL provided as a gate electrode of the drain select transistor DST.

The common source region CSR may be electrically coupled to the common source line CSL shown in FIG. 1. The common source region CSR may be formed in a doped semiconductor structure DPS.

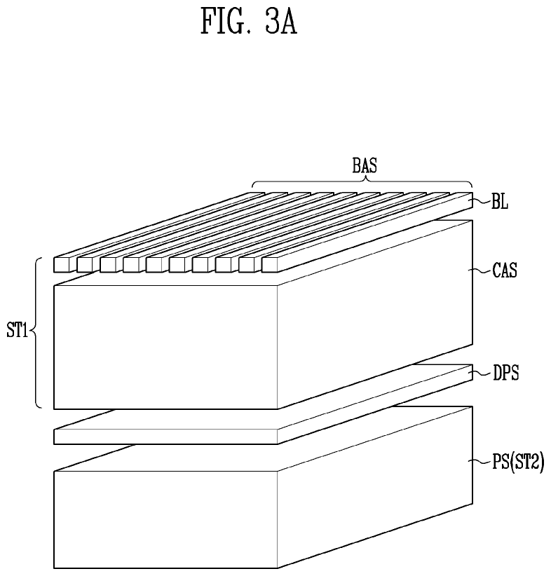

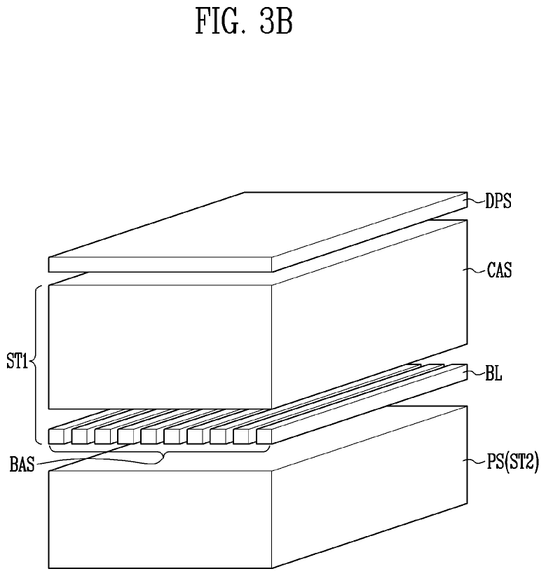

FIGS. 3A and 3B are diagrams illustrating a vertical arrangement of a semiconductor memory device according to embodiments of the present disclosure.

Referring to FIGS. 3A and 3B, a semiconductor memory device may include a first structure ST1, a second structure ST2, and a doped semiconductor structure DSP. The first structure ST1 may include a cell array structure CAS and a bit line array structure BAS. The second structure ST2 may include a peripheral circuit structure PS.

The bit line array structure BAS may include a bit line BL as described above with reference to FIGS. 1 and 2.

The cell array structure CAS may be arranged between the bit line array structure BAS and the doped semiconductor structure DPS. The cell array structure CAS may include a plurality of gate electrodes which are coupled to a plurality of memory cell strings. The plurality of gate electrodes may include the source select line SSL, the plurality of word lines WL, and the drain select line DSL as shown in FIG. 2, and may be spaced apart from each other in a vertical direction. The cell array structure CAS may include a channel pattern (or a channel layer) which passes through a plurality of gate electrodes. The plurality of gate electrodes and the channel pattern (or the channel layer) may have various structures for improving a degree of integration of the memory cell string.

The doped semiconductor structure DPS may include at least one of an n type impurity and a p type impurity. The doped semiconductor structure DPS may include n type impurities which are provided as the common source region CSR shown in FIG. 2. However, the present disclosure is not limited thereto. The doped semiconductor structure DPS may further include p type impurities which are provided as a well region.

The peripheral circuit structure PS may include a region which overlaps the doped semiconductor structure DPS, the cell array structure CAS, and the bit line array structure BAS. The peripheral circuit structure PS may include a plurality of transistors, capacitors, resistors, and the like which form the peripheral circuit 40 as shown in FIG. 1.

As shown in FIG. 3A, the peripheral circuit structure PS may be adjacent to the doped semiconductor structure DPS as shown in FIG. 3A, or may be adjacent to the bit line array structure BAS as shown in FIG. 3A.

Though not shown, each of the first structure ST1 and the second structure ST2 may include at least one of a plurality of interconnections, a plurality of contacts, and a plurality of conductive bonding pads for an electrical connection.

Hereinafter, the first direction DR1 may be an X-axis direction, and the second direction DR2 and the third direction DR3 may correspond to a −Y-axis direction and a +Y-axis direction, respectively, which are opposite to each other in an XY plane. In addition, a fourth direction DR4 to be described below may correspond to a vertical direction crossing the XY plane, and may be, for example, a Z-axis direction.

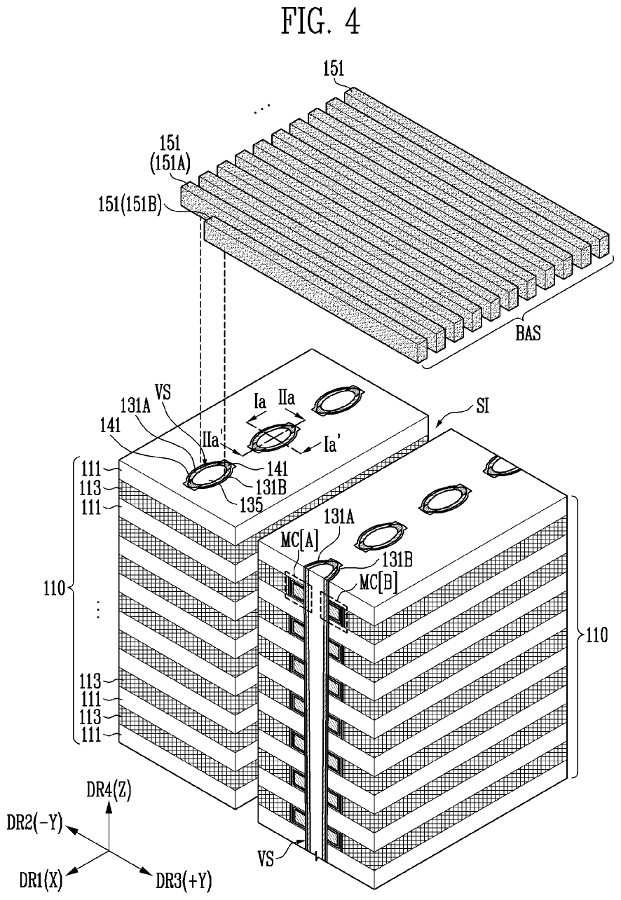

FIGS. 4, 5A, 5B, 5C, 6A, and 6B are diagrams illustrating a semiconductor memory device according to an embodiment of the present disclosure.

FIG. 4 is a perspective view illustrating a part of a semiconductor memory device. Referring to FIG. 4, a semiconductor memory device may include gate stack structures 110 which are adjacent to each other with a slit SI interposed therebetween, a vertical structure VS which passes through each of the gate stack structures 110, and a bit line array structure BAS.

Each gate stack structure 110 may include a plurality of conductive layers 113 which are spaced apart from each other in the fourth direction DR4 and stacked on each other. Each gate stack structure 110 may further include a plurality of interlayer insulating layers 111 which are arranged alternately with the plurality of conductive layers 113 in the fourth direction DR4. In an embodiment, each of the plurality of conductive layers 113 and the plurality of interlayer insulating layers 111 may be formed in a shape of a plate which extends along the XY plane.

The plurality of conductive layers 113 may serve as the plurality of word lines WL as shown in FIG. 2. Each of the conductive layers 113 may include at least one of a doped semiconductor layer, a metal layer, and a conductive metal nitride layer. The doped semiconductor layer may include a doped silicon layer. The metal layer may include tungsten, copper, molybdenum, or the like. The conductive metal nitride layer may include a tantalum nitride, a tantalum nitride, or the like. The plurality of interlayer insulating layers 111 may include silicon oxide layers or the like.

The vertical structure VS may extend in the fourth direction DR4 to pass through the plurality of conductive layers 113 and the plurality of interlayer insulating layers 111 of the gate stack structure 110. The vertical structure VS may have a greater width in the first direction DR1 than in the second direction DR2 on the XY plane. The vertical structure VS may include an insulating pillar 135, a semiconductor oxide layer 141, a first channel pattern 131A, and a second channel pattern 131B. The first channel pattern 131A and the second channel pattern 131B may be separated from each other with the insulating pillar 135 and the semiconductor oxide layer 141 interposed therebetween on the XY plane. The insulating pillar 135 may include a first outer wall facing the second direction DR2 and a second outer wall facing the third direction DR3. The second direction DR2 and the third direction DR3 are opposite to each other on the XY plane. The first channel pattern 131A may extend in the fourth direction DR4 along the first outer wall of the insulating pillar 135. The second channel pattern 131B may extend in the fourth direction DR4 along the second outer wall of the insulating pillar 135. Each of the first channel pattern 131A and the second channel pattern 131B may serve as a channel of a memory cell string corresponding thereto. Each of the first channel pattern 131A and the second channel pattern 131B may include a semiconductor material. According to an embodiment, each of the first channel pattern 131A and the second channel pattern 131B may include silicon (Si), germanium (Ge), or a mixture thereof. The semiconductor oxide layer 141 may be obtained by oxidation of the semiconductor material of each of the first and second channel patterns 131A and 131B.

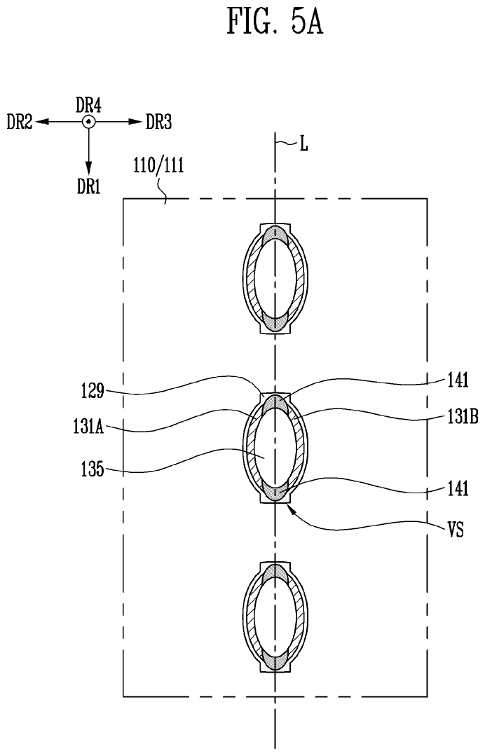

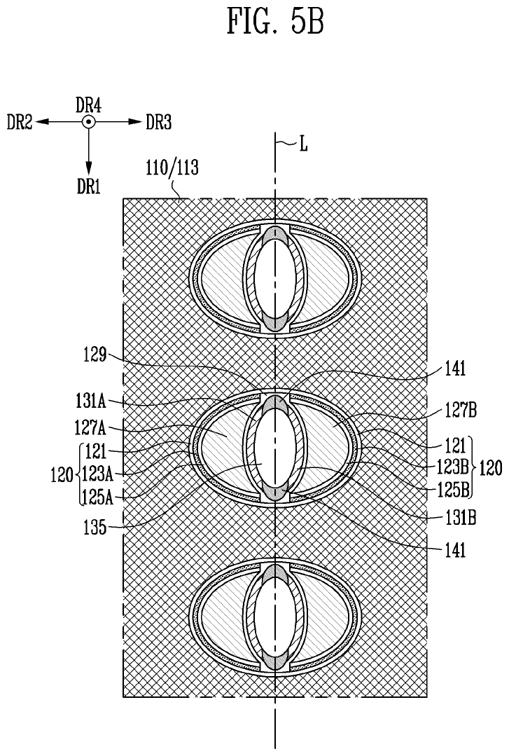

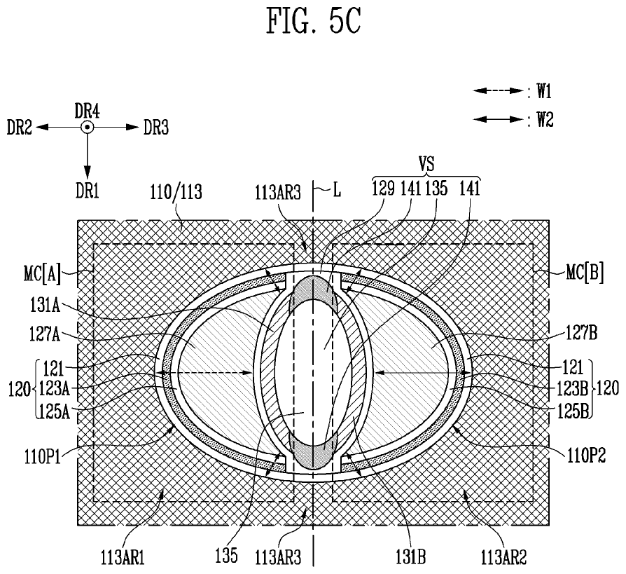

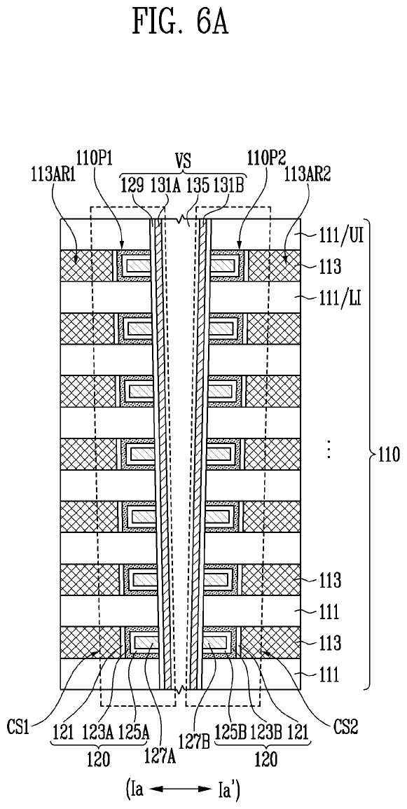

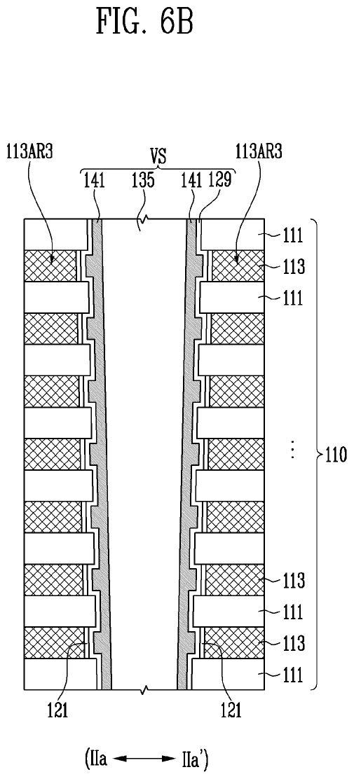

A first memory cell MC[A] may be defined at an intersection between each of the conductive layers 113 and the first channel pattern 131A. A second memory cell MC[B] may be defined at an intersection between each of the conductive layers 113 and the second channel pattern 131B. The structure of each of the first memory cell MC[A] and the second memory cell MC[B] will be described below with reference to FIGS. 5A to 5C and FIGS. 6A and 6B.

The bit line array structure BAS may include a plurality of bit lines 151. Each of the bit lines 151 may include a region which overlaps the slit SI and regions extending in the second direction DR2 and the third direction DR3 from the overlapping region. The plurality of bit lines 151 may include a first bit line 151A which is connected to the first channel pattern 131A and a second bit line 151B which is connected to the second channel pattern 131B. The first channel pattern 131A and the second channel pattern 131B which are controlled by the same conductive layer 113 may be controlled by the first bit line 151A and the second bit line 151B, respectively, which are separated from each other.

Though not shown, a first doped capping pattern may be coupled to an end portion of the first channel pattern 131A toward the bit line array structure BAS, and a second doped capping pattern may be coupled to an end portion of the second channel pattern 131B toward the bit line array structure BAS. Each of the first and second doped capping patterns may include a semiconductor layer which includes at least one of an n type impurity and a p type impurity. According to an embodiment, each of the first and second doped capping patterns may include n type impurities as majority carriers.

FIG. 5A is a plan view illustrating a semiconductor memory device at a level where the interlayer insulating layer 111 shown in FIG. 4 is arranged. FIG. 5B is a plan view illustrating a semiconductor memory device at a level where the conductive layer 113 shown in FIG. 4 is arranged. FIG. 5C is an enlarged plan view of a part of the structure shown in FIG. 5B.

Referring to FIGS. 5A to 5C, each of the conductive layers 113 and the interlayer insulating layers 111 of the gate stack structure 110 may extend in the second direction DR2 and the third direction DR3 on the basis of a center line L. The center line L may extend in the first direction DR1 on the plane. The conductive layer 113 may overlap the interlayer insulating layer 111 of the gate stack structure 110 in the fourth direction DR4. The interlayer insulating layer 111 may protrude toward the first channel pattern 131A and the second channel pattern 131B more than the conductive layer 113. As a result, a first lateral groove 110P1 and a second lateral groove 110P2 may be defined in the gate stack structure 110. The first lateral groove 110P1 and the second lateral groove 110P2 may be symmetrical relative to each other with respect to the center line L. Each of the first lateral groove 110P1 and the second lateral groove 110P2 may have a substantially semi-elliptical shape.

The conductive layer 113 may include a first area 113AR1, a second area 113AR2, and a third area 113AR3. The first area 113AR1 may face the first channel pattern 131A and the second area 113AR2 may face the second channel pattern 131B. The first area 113AR1 may include a side portion which is curved along the first lateral groove 110P1. In an embodiment, the first area 113AR1 may include a side portion which is curved along the first lateral groove 110P1 and faces the convex side portion of the first channel pattern 131A as shown in FIG. 5C. The second area 113AR2 may include a side portion which is curved along the second lateral groove 110P2. In an embodiment, the second area 113AR2 may include a side portion which is curved along the second lateral groove 110P2 and faces the convex side portion of the second channel pattern 131B as shown in FIG. 5C. The third area 113AR3 may couple the first area 113AR1 and the second area 113AR2 to each other and extend between the vertical structure VS and another vertical structure VS adjacent thereto in the first direction DR1.

The vertical structure VS may include a tunnel insulating layer 129 which has substantially a tubular shape. The tunnel insulating layer 129 may extend to cover an outer wall of the first channel pattern 131A toward the first area 113AR1 of the conductive layer 113 and an outer wall of the second channel pattern 131B toward the second area 113AR2. The tunnel insulating layer 129 may extend between the third area 113AR3 of the conductive layer 113 and the semiconductor oxide layer 141 of the vertical structure VS. The tunnel insulating layer 129 may include an insulating material which enables charge tunneling. According to an embodiment, the tunnel insulating layer 129 may include an oxide such as a silicon oxide layer.

The insulating pillar 135 of the vertical structure VS may be disposed at a central region of the tunnel insulating layer 129 having the substantially tubular shape. The insulating pillar 135 may overlap the center line L. The insulating pillar 135 may be convex toward the second direction DR2 and the third direction DR3 with respect to the center line L. In a plan view, the insulating pillar 135 may have an elliptical shape and the center line L may overlap a major axis of the insulating pillar 135.

The semiconductor oxide layer 141 of the vertical structure VS may overlap the center line L and be disposed between an end portion of the first channel pattern 131A and an end portion of the second channel pattern 131B. The semiconductor oxide layer 141 of the vertical structure VS may be interposed between the tunnel insulating layer 129 and the insulating pillar 135.

As the semiconductor oxide layer 141 and the insulating pillar 135 which are disposed along the center line L are interposed between the first channel pattern 131A and the second channel pattern 131B, the first channel pattern 131A may be separated from the second channel pattern 131B. Each of the first channel pattern 131A and the second channel pattern 131B may be curved along the convex outer wall of the insulating pillar 135 corresponding thereto.

The first memory cell MC[A] may include a first data storage pattern 127A which is disposed in the first lateral groove 110P1. The second memory cell MC[B] may further include a second data storage pattern 127B which is disposed in the second lateral groove 110P2. The first data storage pattern 127A may be disposed between the first area 113AR1 of the conductive layer 113 and the first channel pattern 131A, thereby forming the first memory cell MC[A] which is controlled by the conductive layer 113 and the first channel pattern 131A. The second data storage pattern 127B may be disposed between the second area 113AR2 of the conductive layer 113 and the second channel pattern 131B, thereby forming the second memory cell MC[B] which is controlled by the conductive layer 113 and the second channel pattern 131B.

The first data storage pattern 127A and the second data storage pattern 127B may be symmetrical to each other with respect to the center line L. Each of the first data storage pattern 127A and the second data storage pattern 127B may have a shape corresponding to that of the lateral groove corresponding thereto. According to an embodiment, the distance between the conductive layer 113 and each of the first channel pattern 131A and the second channel pattern 131B may decrease toward the center line L. For example, in an embodiment, a variable distance between the first channel pattern 131A and the conductive layer 113 decreases with decreasing distance of the first channel pattern 131A and the conductive layer 113 from the center line L as shown in FIG. 5C. For example, in an embodiment, a variable distance between the second channel pattern 131B and the conductive layer 113 decreases with decreasing distance of the second channel pattern 131B and the conductive layer 113 from the center line L as shown in FIG. 5C. Thus, in an embodiment, as the distance between the conductive layer 113 and the first channel pattern 131A is measured closer to the center line L the distance between the conductive layer 113 and the first channel pattern 131A decreases as shown in FIG. 5C. Thus, in an embodiment, as the distance between the conductive layer 113 and the second channel pattern 131B is measured closer to the center line L the distance between the conductive layer 113 and second channel pattern 131B decreases as shown in FIG. 5C. Accordingly, in a plan view, a width of each of the first lateral groove 110P1 and the second lateral groove 110P2 may decrease toward the center line L. Thus, a width of each of the first data storage pattern 127A and the second data storage pattern 127B may decrease toward the center line L. For example, in an embodiment, a width of the first data storage pattern 127A decreases with decreasing distance of the first data storage pattern 127A from the center line L. For example, in an embodiment, a width of the second data storage pattern 127B decreases with decreasing distance of the second data storage pattern 127B from the center line L. According to an embodiment, in a plan view, a variable width W1 of the first lateral groove 110P1 between the conductive layer 113 and the first channel pattern 131A may decrease toward an end of the first lateral groove 110P1. Also, in an embodiment, in a plane view, a variable width W2 of the second lateral groove 110P2 between the conductive layer 113 and the second channel pattern 131B may decrease toward an end of the second lateral groove 110P2. Thus, in an embodiment, a width of the first data storage pattern 127A may decrease as the first data storage pattern 127A is located closer to the center line L as shown in FIG. 5C. Likewise, in an embodiment, a width of the second data storage pattern 127B may decrease as the second data storage pattern 127B is located closer to the center line L as shown in FIG. 5C.

According to the above-described embodiment of the present disclosure, the data storage pattern 127A or 127B may have an inner wall toward the channel pattern 131A or 131B and an outer wall toward the conductive layer 113. In an embodiment, the width of the data storage pattern 127A or 127B may decrease toward the ends as shown in FIG. 5C. Though not shown, contrary to the embodiments of the present disclosure, when a uniform width of a data storage pattern is maintained, an electric field between the channel pattern 131A or 131B and the conductive layer 113 may decrease toward an end of the data storage pattern. According to an embodiment of the present disclosure, because the width of the data storage pattern 127A or 127B decreases towards the ends as these ends are located closer to the center line L, the electric field between the channel pattern 131A or 131B and the conductive layer 113 may be prevented or mitigated from decreasing toward the ends. Accordingly, in an embodiment, operational reliability of the semiconductor memory device may be improved.

Each of the first data storage pattern 127A and the second data storage pattern 127B may include a material layer which stores data being varied by using Fowler-Nordheim tunneling. According to an embodiment, each of the first data storage pattern 127A and the second data storage pattern 127B may include a charge trap insulating layer, a floating gate layer, or an insulating layer including conductive nanodots. The charge trap insulating layer may include a silicon nitride layer. The floating gate layer may include a silicon layer. However, the embodiments are not limited thereto. Each of the first data storage pattern 127A and the second data storage pattern 127B may include a material layer which stores information based on other operating principles other than Fowler-Nordheim tunneling. According to an embodiment, each of the first data storage pattern 127A and the second data storage pattern 127B may include a phase-change material layer, a ferroelectric layer, or the like.

The semiconductor memory device may further include a blocking insulating layer 120 which extends along a side portion of each of the first area 113AR1 and the second area 113AR2 of the conductive layer 113. The blocking insulating layer 120 may include a first dielectric layer 121, a second dielectric layer 123A or 123B, and a third dielectric layer 125A or 125B. The first dielectric layer 121 may extend along a side portion of the third area 113AR3 of the conductive layer 113 and be interposed between the third area 113AR3 of the conductive layer 113 and the tunnel insulating layer 129. The first dielectric layer 121 may include an oxide layer such as a silicon oxide layer and a silicon nitride layer. The second dielectric layer 123A or 123B may include a nitride layer such as a silicon nitride layer. The third dielectric layer 125A or 125B may include an oxide layer such as a silicon oxynitride layer. Each of the second and third dielectric layers may be separated into a first pattern 123A or 125A between the first area 113AR1 of the conductive layer 113 and the first data storage pattern 127A and a second pattern 123B or 125B between the second area 113AR2 of the conductive layer 113 and the second data storage pattern 127B. The tunnel insulating layer 129 may extend between the first pattern 123A or 125A and the second pattern 123B or 125B of each of the second dielectric layer and the third dielectric layer.

FIG. 6A is a cross-sectional diagram of a semiconductor memory device taken along line Ia-Ia′ of FIG. 4. FIG. 6B is a cross-sectional diagram illustrating a semiconductor memory device taken along line IIa-IIa′ of FIG. 4.

Referring to FIGS. 6A and 6B, the first memory cell string CS1 and the second memory cell string CS2 may be formed at both sides of the vertical structure VS.

The first channel pattern 131A of the first memory cell string CS1 may be controlled by the first bit line 151A shown in FIG. 4. The second channel pattern 131B of the second memory cell string CS2 may be controlled by the second bit line 151B shown in FIG. 4.

The plurality of conductive layers 113 of the gate stack structure 110 may serve as a plurality of word lines. A plurality of first memory cells of the first memory cell string CS1 may be formed between the plurality of conductive layers 113 and the first channel pattern 131A. A plurality of second memory cells of the second memory cell string CS2 may be formed between the plurality of conductive layers 113 and the second channel pattern 131B.

A plurality of first data storage patterns 127A of the plurality of first memory cells may be disposed in a plurality of first lateral grooves 110P1, respectively, which are separated from each other in the fourth direction DR4 by the plurality of interlayer insulating layers 111. A plurality of second data storage patterns 127B of the plurality of second memory cells may be disposed in a plurality of second lateral grooves 110P2, respectively, which are separated from each other in the fourth direction DR4 by the plurality of interlayer insulating layers 111. For example, the plurality of interlayer insulating layers 111 may include a lower interlayer insulating layer LI and an upper interlayer insulating layer UI which is separated from a lower interlayer insulating layer LI in the fourth direction DR4. The lower interlayer insulating layer LI and the upper interlayer insulating layer UI may protrude toward the first channel pattern 131A and the second channel pattern 131B more than the conductive layer 113 therebetween. As a result, the first lateral groove 110P1 may be defined between the conductive layer 113 and the first channel pattern 131A, and the second lateral groove 110P2 may be defined between the conductive layer 113 and the second channel pattern 131B. The first lateral groove 110P1 and the second lateral groove 110P2 may be separated from each other by the vertical structure VS.

According to an embodiment of the present disclosure, the charges stored in the first data storage pattern 127A and the second data storage pattern 127B may be prevented or mitigated from moving in the fourth direction DR4, so that the operational reliability of the semiconductor memory device may be improved.

The first dielectric layer 121 of the blocking insulating layer 120 may have a ring shape which is formed along side portions of the first area 113AR1, the second area 113AR2, and the third area 113AR312 of each conductive layer 113. The second dielectric layer 123A or 123B and the third dielectric layer 125A or 125B of the blocking insulating layer 120 may be interposed between the data storage pattern 127A or 127B corresponding thereto and the first dielectric layer 121 and may extend between the data storage pattern 127A or 127B corresponding thereto and the interlayer insulating layer 111. The interlayer insulating layer 111 may contact the second dielectric layer 123A or 123B without interposing the first dielectric layer 121. The interlayer insulating layer 111 may contact the vertical structure VS without interposing the blocking insulating layer 120.

Each of the tunnel insulating layer 129, the first channel pattern 131A, the insulating pillar 135, the semiconductor oxide layer 141, and the second channel pattern 131B may extend in the fourth direction DR4 to pass through the plurality of interlayer insulating layers 111 and the plurality of conductive layers 113.

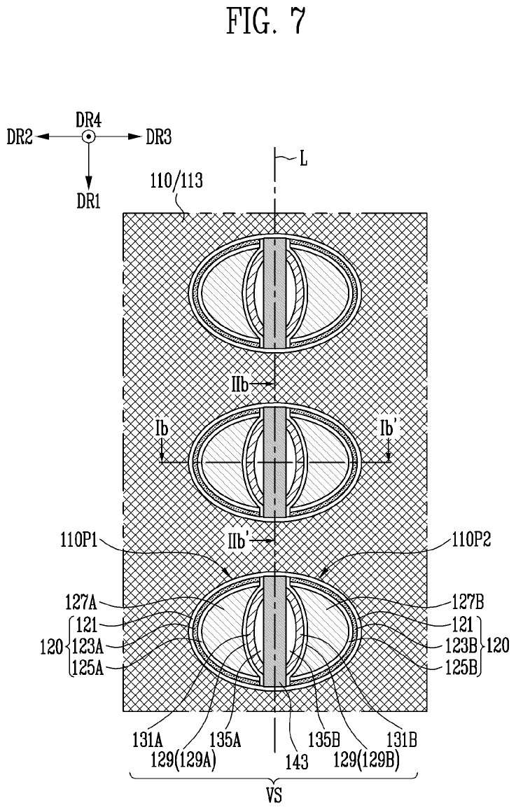

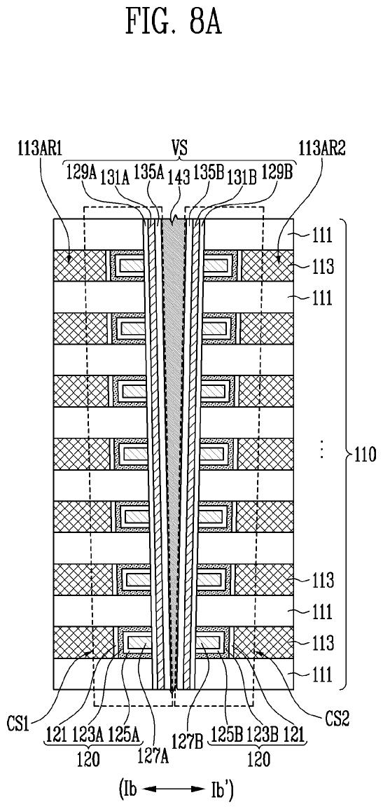

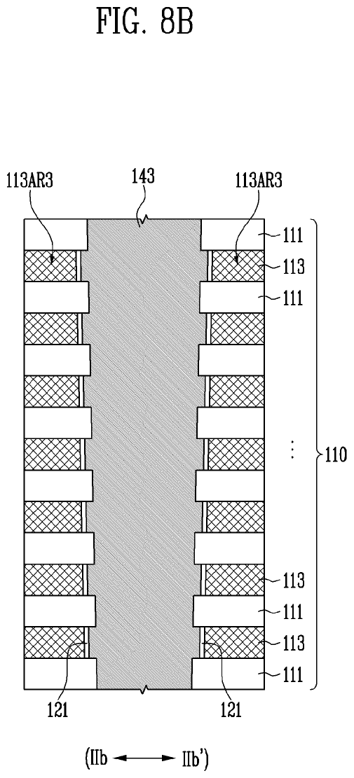

FIGS. 7, 8A, and 8B are diagrams illustrating a semiconductor memory device according to an embodiment of the present disclosure.

FIG. 7 is a plan view illustrating a semiconductor memory device. FIG. 8A is a cross-sectional diagram of a semiconductor memory device taken along line Ib-Ib′ of FIG. 7. FIG. 8B is a cross-sectional diagram illustrating a semiconductor memory device taken along line IIb-IIb′ of FIG. 7. Hereinafter, a description of the same configurations as those described with reference to FIGS. 4, 5A to 5C, and 6A and 6B is simplified or omitted.

Referring to FIGS. 7, 8A, and 8B, a gate stack structure 110 of the semiconductor memory device may include a plurality of interlayer insulating layers 111 and a plurality of conductive layers 113 which are alternately stacked in the fourth direction DR4. The gate stack structure 110 may be penetrated by a vertical structure VS.

The vertical structure VS may include an insulating partition wall 143, a first channel pattern 131A, a second channel pattern 131B, a pillar pattern 135A or 135B, and a tunnel insulating layer 129. Each of the insulating partition wall 143, the first channel pattern 131A, the second channel pattern 131B, the pillar pattern 135A or 135B, and the tunnel insulating layer 129 may extend in the fourth direction DR4 to pass through the plurality of conducive layers 113 and the plurality of interlayer insulating layers 111.

The insulating partition wall 143 may extend in the first direction DR1 and overlap a center line L which passes through the center of the vertical structure VS. The insulating partition wall 143 may be wider in the first direction DR1 than in the second direction DR2.

The first channel pattern 131A and the second channel pattern 131B may be separated from each other while interposing the insulating partition wall 143. The pillar pattern 135A or 135B may be interposed between the insulating partition wall 143 and each of the first channel pattern 131A and the second channel pattern 131B. The pillar pattern 135A or 135B and the insulating partition wall 143 may include the same as or different materials from each other. The pillar pattern 135A or 135B may include a side portion which is convex toward the channel pattern 131A or 131B corresponding thereto.

The tunnel insulating layer 129 may be separated into a first tunnel insulating pattern 129A and a second tunnel insulating pattern 129B by the insulating partition wall 143. The first tunnel insulating pattern 129A may extend along an outer wall of the first channel pattern 131A toward a first area 113AR1 of the conductive layer 113. The second tunnel insulating pattern 129B may extend along an outer wall of the second channel pattern 131B toward a second area 113AR2 of the conductive layer 113. However, embodiments of the present disclosure are not limited thereto. According to another embodiment, the tunnel insulating layer 129 may extend between a third area 113AR3 of the conductive layer 113 and the insulating partition wall 143 and have substantially a tubular shape as shown in FIGS. 5A to 5C.

The plurality of interlayer insulating layers 111 may protrude toward the first channel pattern 131A and the second channel pattern 131B more than the plurality of conductive layers 113. As a result, a first lateral groove 110P1 and a second lateral groove 110P2 may be defined in the gate stack structure 110.

The first channel pattern 131A may be separated from the second channel pattern 131B by the insulating partition wall 143 arranged along the center line L. The first channel pattern 131A may serve as the channel region of a first memory cell string CS1. The second channel pattern 131B may serve as the channel region of a second memory cell string CS2.

A first memory cell of the first memory cell string CS1 may include a first data storage pattern 127A which is disposed in the first lateral groove 110P1. A second memory cell of the second memory cell string CS2 may include a second data storage pattern 127B which is disposed in the second lateral groove 110P2. The first data storage pattern 127A may be disposed between the first area 113AR1 of the conductive layer 113 and the first channel pattern 131A, thereby forming the first memory cell which is controlled by the conductive layer 113 and the first channel pattern 131A. The second data storage pattern 127B may be disposed between the second area 113AR2 of the conductive layer 113 and the second channel pattern 131B, thereby forming the second memory cell which is controlled by the conductive layer 113 and the second channel pattern 131B.

A width of each of the first lateral groove 110P1, the second lateral groove 110P2, the first data storage pattern 127A, and the second data storage pattern 127B may decrease toward the center line L.

A blocking insulating layer 120 of the semiconductor memory device may include a first dielectric layer 121 extending along the side portion of each of the first area 113AR1 and the second area 113AR2. The first dielectric layer 121 of the blocking insulating layer 120 may extend along a side portion of the third area 113AR3 of the conductive layer 113 and have a ring shape. However, embodiments of the present disclosure are not limited thereto. According to another embodiment, the insulating partition wall 143 may extend toward the third area 113AR3 of the conductive layer 113 to pass through the first dielectric layer 121 of the blocking insulating layer 120. The first dielectric layer 121 of the blocking insulating layer 120 may be separated into a first pattern between the first area 113AR1 of the conductive layer 113 and the first data storage pattern 127A and a second pattern between the second area 113AR2 of the conductive layer 113 and the second data storage pattern 127B. The blocking insulating layer 120 may further include a second dielectric layer and a third dielectric layer. Each of the second and third dielectric layers of the blocking insulating layer 120 may be separated into a first pattern 123A or 125A between the first area 113AR1 of the conductive layer 113 and the first data storage pattern 127A and a second pattern 123B or 125B between the second area 113AR2 of the conductive layer 113 and the second data storage pattern 127B. The tunnel insulating layer 129 may extend between the first pattern 123A or 125A and the second pattern 123B or 125B of each of the second dielectric layer and the third dielectric layer.

The first channel pattern 131A of the first memory cell string CS1 and the second channel pattern 131B of the second memory cell string CS2 may be controlled by the first bit line 151A and the second bit line 151B, respectively, as shown in FIG. 4.

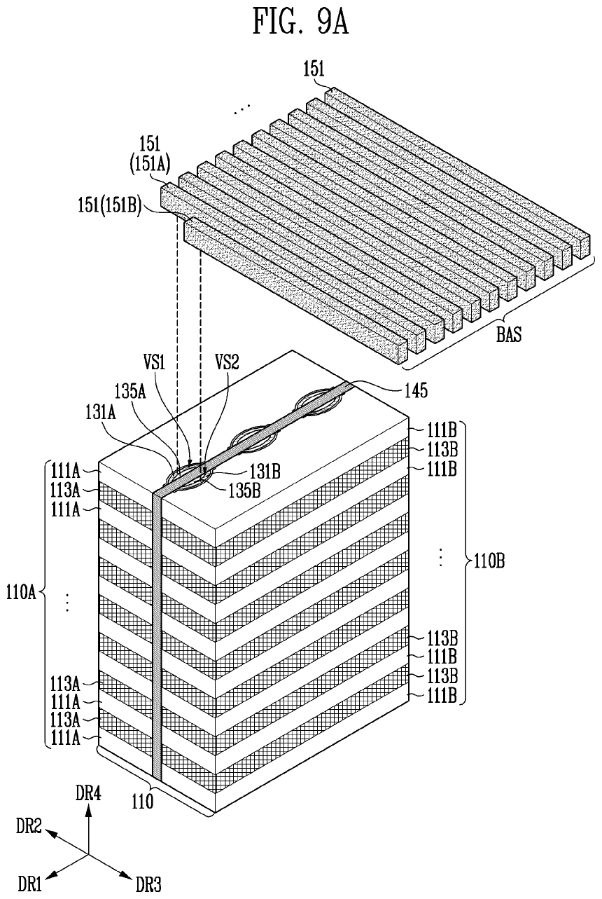

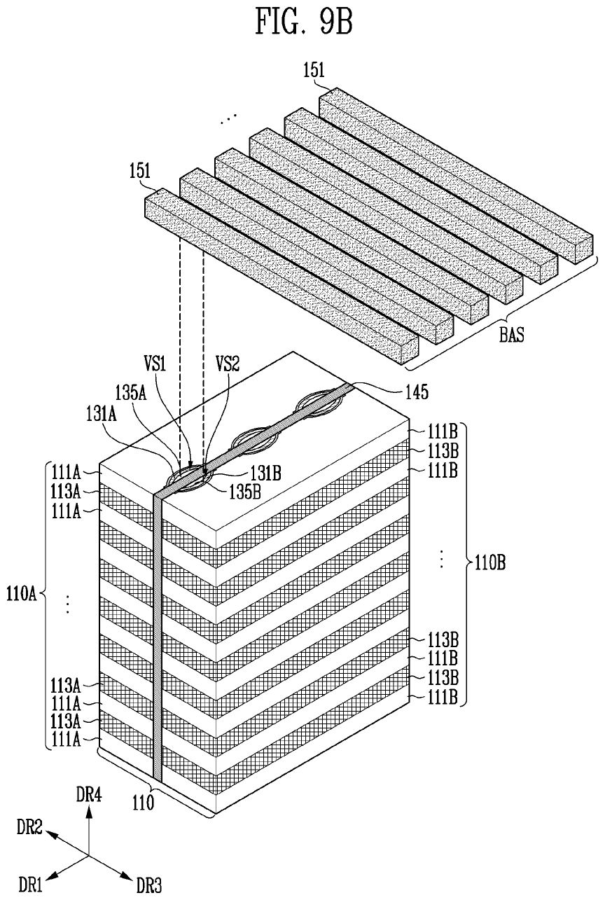

FIGS. 9A and 9B are diagrams illustrating a semiconductor memory device according to embodiments of the present disclosure.

Referring to FIGS. 9A and 9B, the semiconductor memory device may include a gate stack structure 110, a first vertical structure VS1, a second vertical structure VS2, an insulating partition wall 145, and a bit line array structure BAS.

The gate stack structure 110 may be divided by the slit SI shown in FIG. 4. The gate stack structure 110 may include a first sub-stack 110A and a second sub-stack 110B which are separated from each other by the insulating partition wall 145. The insulating partition wall 145 may cross the gate stack structure 110 and extend in the first direction DR1. The first sub-stack 110 may extend in the second direction DR2 from the insulating partition wall 145. The second sub-stack 110B may extend in the third direction DR3 from the insulating partition wall 145.

The first sub-stack 110A may include a plurality of first conductive patterns 113A which are stacked separately from each other in the fourth direction DR4. The second sub-stack 110B may include a plurality of second conductive patterns 113B which are stacked separately from each other in the fourth direction DR4. The first sub-stack 110A may further include a plurality of first interlayer insulating patterns 111A which are arranged alternately with the plurality of first conductive patterns 113A in the fourth direction DR4. The second sub-stack 110B may further include a plurality of second interlayer insulating patterns 111B which are arranged alternately with the plurality of second conductive patterns 113B in the fourth direction DR4. Each of the plurality of first conductive patterns 113A, the plurality of second conductive patterns 113B, the plurality of first interlayer insulating patterns 111A, and the plurality of second interlayer insulating patterns 111B may have a plate shape which extends along a plane. Each of the plurality of first conductive patterns 113A and the plurality of second conductive patterns 113B may serve as the word line WL shown in FIG. 2.

The plurality of first conductive patterns 113A and the plurality of second conductive patterns 113B may include various conductive materials which are exemplified as those of the plurality of conductive layers 113 shown in FIG. 4. The plurality of first interlayer insulating patterns 111A and the plurality of second interlayer insulating patterns 111B may include a silicon oxide layer.

The first vertical structure VS1 may extend in the fourth direction DR4 to pass through the plurality of first conductive patterns 113A and the plurality of first interlayer insulating patterns 111A of the first sub-stack 110A. The second vertical structure VS2 may extend in the fourth direction DR4 to pass through the plurality of second conductive patterns 113B and the plurality of second interlayer insulating patterns 111B of the second sub-stack 110B. Each of the first vertical structure VS1 and the second vertical structure VS2 may include a partition wall-side lateral portion which contacts the insulating partition wall 145. The first vertical structure VS1 and the second vertical structure VS2 may extend in the second direction DR2 and the third direction DR3 opposing each other on the basis of the insulating partition wall 145. The first vertical structure VS1 may include a gate-side lateral portion which is convex in the second direction DR2. The second vertical structure VS2 may include a gate-side lateral portion which is convex in the third direction DR3.

The first vertical structure VS1 may include the first channel pattern 131A and the second vertical structure VS2 may include the second channel pattern 131B. Each of the first vertical structure VS1 and the second vertical structure VS2 may further include the pillar pattern 135A or 135B which is arranged between the channel pattern 131A or 131B corresponding thereto and the insulating partition wall 145. The pillar pattern 135A or 135B may include the same or different insulating material from the insulating partition wall 145. Each of the first channel pattern 131A and the second channel pattern 131B may serve as a channel of a memory cell string corresponding thereto. Each of the first channel pattern 131A and the second channel pattern 131B may include the same material as described above with reference to FIG. 4. The first channel pattern 131A and the second channel pattern 131B may be connected to the plurality of bit lines 151 of the bit line array structure BAS in various manners.

Referring to FIG. 9A, the plurality of bit lines 151 may include a first bit line 151A which is connected to the first channel pattern 131A and a second bit line 151B which is connected to the second channel pattern 131B. Therefore, the first channel pattern 131A may be controlled by the first bit line 151A and the first conductive pattern 113A. The second channel pattern 131B may be controlled by the second bit line 151B and the second conductive pattern 113B.

Referring to FIG. 9B, each of the bit lines 151 may be connected to the first channel pattern 131A and the second channel pattern 131B which face each other. The first channel pattern 131A and the second channel pattern 131B which are connected to the same bit line 151 may be controlled by the first conductive pattern 113A and the second conductive pattern 113B, respectively.

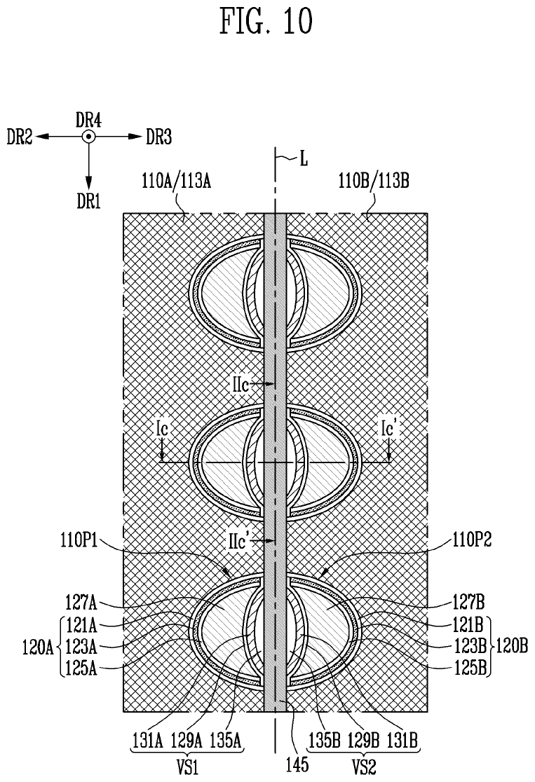

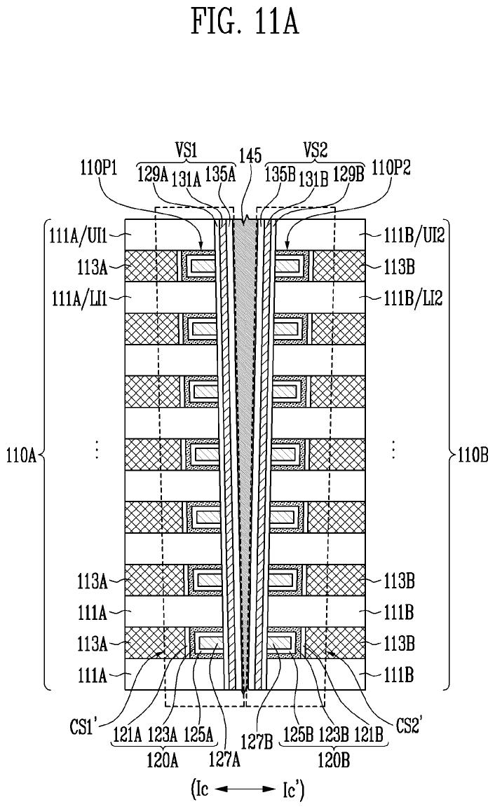

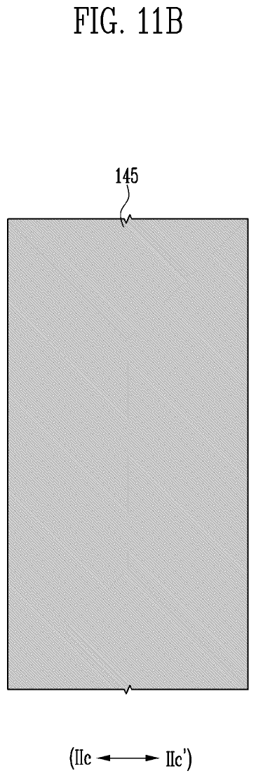

The first channel pattern 131A may serve as a channel region of the first memory cell. The second channel pattern 131B may serve as a channel region of the second memory cell. The first data storage pattern of the first memory cell may be disposed in the first lateral groove between the first vertical structure VS1 and each of the first conductive patterns 113A. The second data storage pattern of the second memory cell may be disposed in the second lateral groove between the second vertical structure VS2 and each of the second conductive patterns 113B. The structure of the first data storage pattern and the second data storage pattern will be described below with reference to FIGS. 10, 11A, and 11B.

FIGS. 10, 11A, and 11B are diagrams illustrating a semiconductor memory device shown in FIG. 9A or 9B.

FIG. 10 is a plan view illustrating a semiconductor memory device shown in FIG. 9A or 9B. Hereinafter, a description of the same components as those in the embodiment described above with reference to FIGS. 5A to 5C will be simplified or omitted.

Referring to FIG. 10, a center line L may be defined along the insulating partition wall 145 in the first direction DR1. The first conductive pattern 113A of the first sub-stack 110A and the second conductive pattern 113B of the second sub-stack 110B may extend in the second direction DR2 and the third direction DR3 opposing each other with respect to the center line L. In a plane view, the center line L may be interposed between the first conductive pattern 113A and the second conductive pattern 113B. The first interlayer insulating pattern 111A of the first sub-stack 110A as shown in FIG. 9A or 9B and the second interlayer insulating pattern 111B of the second sub-stack 110B shown in FIG. 9A or 9B may extend in the second direction DR2 and the third direction DR3 opposing each other with respect to the center line L. In a plane view, the center line L may be interposed between the first interlayer insulating pattern 111A shown in FIG. 9A or 9B and the second interlayer insulating pattern 111B shown in FIG. 9A or 9B. The first interlayer insulating pattern 111A of the first sub-stack 110A as shown in FIG. 9A or 9B may protrude toward the first vertical structure VS1 more than the first conductive pattern 113A. As a result, the first lateral groove 110P1 may be defined in the first sub-stack 110A. The second interlayer insulating pattern 111B of the second sub-stack 110B as shown in FIG. 9A or 9B may protrude toward the second vertical structure VS2 more than the second conductive pattern 113B. As a result, the second lateral groove 110P2 may be defined in the second sub-stack 110B. The first lateral groove 110P1 and the second lateral groove 110P2 may have the same structure as described above with reference to FIGS. 5A to 5C.

The first conductive pattern 113A may include a side portion which is curved along the first lateral groove 110P1. The second conductive pattern 113B may include a side portion which is curved along the second lateral groove 110P2. The first data storage pattern 127A and a first blocking insulating pattern 120A may be arranged in the first lateral groove 110P1. The second data storage pattern 127B and a second blocking insulating pattern 120B may be arranged in the second lateral groove 110P2.

The first blocking insulating pattern 120A may extend along an inner wall of the first conductive pattern 113A toward the first channel pattern 131A. The second blocking insulating pattern 120B may extend along an inner wall of the second conductive pattern 113B toward the second channel pattern 131B. Each of the first blocking insulating pattern 120A and the second blocking insulating pattern 120B may include a first dielectric layer 121A or 121B, a second dielectric layer 123A or 123B, and a third dielectric layer 125A or 125B. The first dielectric layer 121A or 121B, the second dielectric layer 123A or 123B, and the third dielectric layer 125A or 125B may include the materials described above with reference to FIGS. 5A to 5C. Each of the first dielectric layer 121A or 121B, the second dielectric layer 123A or 123B, and the third dielectric layer 125A or 125B may be separated into the first pattern 121A, 123A, or 125A and the second pattern 121B, 123B, or 125B.

The insulating partition wall 145 may pass between the pillar pattern 135A of the first vertical structure VS1 and the pillar pattern 135B of the second vertical structure VS2 and pass through the first channel pattern 131A and the second channel pattern 131B. The insulating partition wall 145 may pass between the first blocking insulating pattern 120A and the second blocking insulating pattern 120B and pass through the first channel pattern 113A and the second conductive pattern 113B.

The first vertical structure VS1 may further include a first tunnel insulating pattern 129A and the second vertical structure VS2 may further include a second tunnel insulating pattern 129B. The first tunnel insulating pattern 129A may surround the outer wall of the first channel pattern 131A toward the first conductive pattern 113A. The second tunnel insulating pattern 129B may surround the outer wall of the second channel pattern 131B. Each of the first tunnel insulating pattern 129A and the second tunnel insulating pattern 129B may include an insulating material which enables charge tunneling.

The first data storage pattern 127A may be interposed between the first blocking insulating pattern 120A and the first tunnel insulating pattern 129A. The second data storage pattern 127B may be interposed between the second blocking insulating pattern 120B and the second tunnel insulating pattern 129B. The first data storage pattern 127A and the second data storage pattern 127B may be symmetrical to each other with respect to the center line L. Each of the first data storage pattern 127A and the second data storage pattern 127B may have a shape corresponding to that of the lateral groove corresponding thereto. According to an embodiment, the distance between the first channel pattern 131A and the first conductive pattern 113A and the distance between the second channel pattern 131B and the second channel pattern 131B and the second conductive pattern 113B may decrease toward the center line L. For example, in an embodiment, a variable distance between the first channel pattern 131A and the first conductive pattern 113A decreases with decreasing distance of the first channel pattern 131A and the first conductive pattern 113A from the center line L. For example, in an embodiment, a variable distance between the second channel pattern 131B and the second conductive pattern 113B decreases with decreasing distance of the second channel pattern 131B and the second conductive pattern 113B from the center line L. In response, the width of each of the first lateral groove 110P1 and the second lateral groove 110P2 may decrease toward the center line L. Accordingly, the width of each of the first data storage pattern 127A and the second data storage pattern 127B may decrease toward the center line L. The first data storage pattern 127A and the second data storage pattern 127B may include the materials which are described above with reference to FIGS. 5A to 5C.

FIG. 11A is a cross-sectional diagram of a semiconductor memory device taken along line Ic-Ic′ of FIG. 10. FIG. 11B is a cross-sectional diagram illustrating a semiconductor memory device taken along line IIc-IIc′ of FIG. 10. Hereinafter, a description of the same components as those in the embodiment described above with reference to FIGS. 6A and 6C will be simplified or omitted.

Referring to FIGS. 11A and 11B, a first memory cell string CS1′ may be defined along the first vertical structure VS1, and a second memory cell string CS2′ may be defined along the second vertical structure VS2. The first blocking insulating pattern 120A, the first data storage pattern 127A, the first tunnel insulating pattern 129A, and the first channel pattern 131A of the first memory cell string CS1′ may be spaced apart from the second blocking insulating pattern 120B, the second data storage pattern 127B, the second tunnel insulating pattern 129B, and the second channel pattern 131B of the second memory cell string CS2′ through the insulating partition wall 145. Accordingly, interference between operations of the first memory cell string CS1′ and the second memory cell string CS2′ may be reduced, so that operational reliability of a semiconductor memory device may be improved.

The first conductive pattern 113A of the first sub-stack 110A and the second conductive pattern 113B of the second sub-stack 110B may be separated from each other by the insulating partition wall 145. The first interlayer insulating pattern 111A of the first sub-stack 110A and the second interlayer insulating pattern 111B of the second sub-stack 110B may be separated from each other by the insulating partition wall 145.

The first memory cell string CS1′ may include a plurality of first memory cells which are connected in series by the first channel pattern 131A. The plurality of first data storage patterns 127A of the plurality of first memory cells may be disposed in a plurality of first lateral grooves 110P1, respectively, which are separated from each other in the fourth direction DR4 by the plurality of first interlayer insulating patterns 111A. For example, the plurality of first interlayer insulating patterns 111A may include a first lower interlayer insulating pattern LI1 and a first upper interlayer insulating pattern UI1 which is separated from the first lower interlayer insulating pattern LI1 in the fourth direction DR4. The first lower interlayer insulating pattern LI1 and the first upper interlayer insulating pattern UI1 may protrude toward the first channel pattern 131A more than the first conductive pattern 113A therebetween. Therefore, the first lateral groove 110P1 may be defined between the first conductive pattern 113A and the first channel pattern 131A. In an embodiment, because the first data storage patterns 127A which are adjacent to each other in the fourth direction DR4 are separated from each other, charges stored in each of the first memory cells may be prevented or mitigated from moving in the fourth direction DR4.

The second memory cell string CS2′ may include a plurality of second memory cells which are connected in series by the second channel pattern 131B. The plurality of second data storage patterns 127B of the plurality of second memory cells may be disposed in a plurality of second lateral grooves 110P2, respectively, which are separated from each other in the fourth direction DR4 by the plurality of second interlayer insulating patterns 111B. For example, the plurality of second interlayer insulating patterns 111B may include a second lower interlayer insulating pattern LI2 and a second upper interlayer insulating pattern UI2 which is separated from the second lower interlayer insulating pattern LI2 in the fourth direction DR4. The second lower interlayer insulating pattern LI2 and the second upper interlayer insulating pattern UI2 may protrude toward the second channel pattern 131B more than the second conductive pattern 113B therebetween. Therefore, the second lateral groove 110P2 may be defined between the second conductive pattern 113B and the second channel pattern 131B. In an embodiment, because the second data storage patterns 127B which are adjacent to each other in the fourth direction DR4 may be separated from each other, charges stored in each of the second memory cells may be prevented or mitigated from moving in the fourth direction DR4.

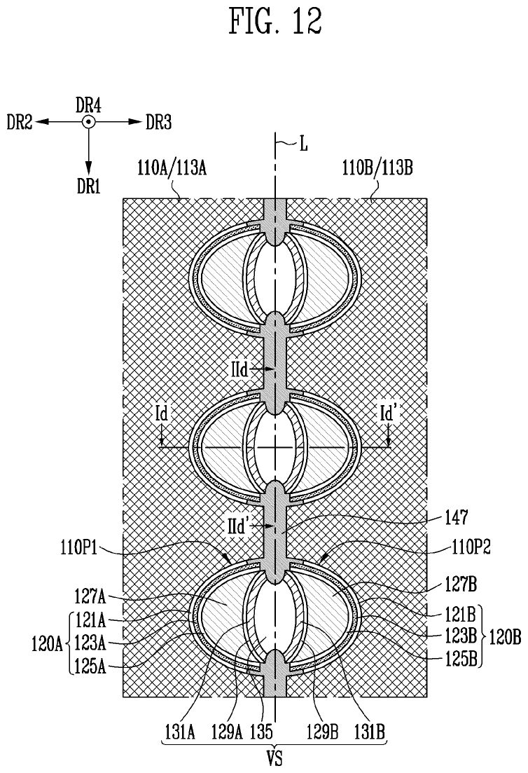

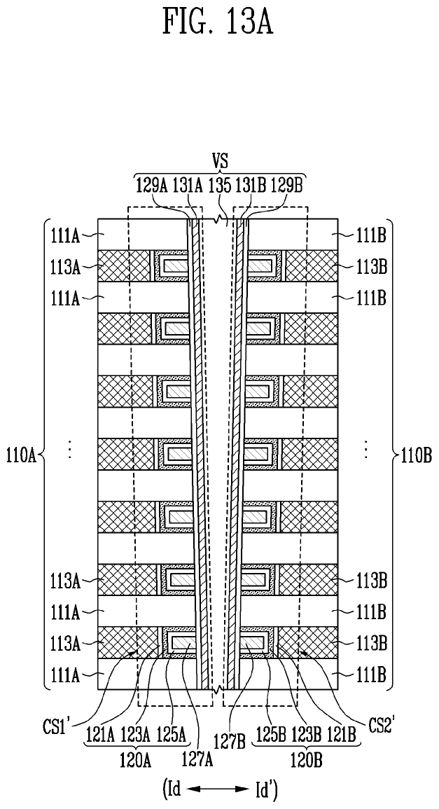

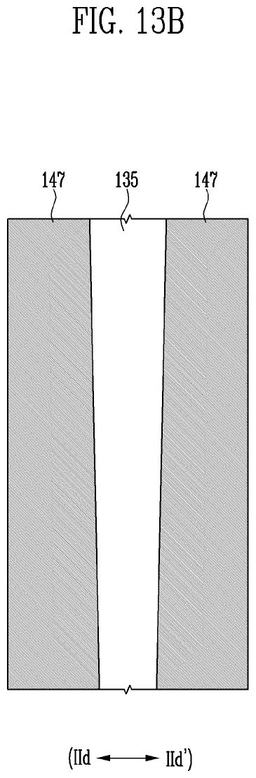

FIGS. 12, 13A, and 13B are diagrams illustrating a semiconductor memory device according to an embodiment of the present disclosure.

FIG. 12 is a plan view illustrating a semiconductor memory device. FIG. 13A is a cross-sectional diagram of a semiconductor memory device taken along line Id-Id′ of FIG. 12. FIG. 13B is a cross-sectional diagram illustrating a semiconductor memory device taken along line IId-IId′ of FIG. 12. Hereinafter, a description of the same configurations as those described with reference to FIGS. 9A, 9B, 10, 11A, and 11B is simplified or omitted.

Referring to FIGS. 12, 13A, and 13B, the semiconductor memory device may include a vertical structure VS, an insulating partition wall 147, a first sub-stack 110A, a second sub-stack 110B, a first blocking insulating pattern 120A, a second blocking insulating pattern 120B, a first data storage pattern 127A, and a second data storage pattern 127B.

The vertical structure VS and the insulating partition wall 147 may be alternately arranged with each other along a center line L which extends in the first direction DR1 on a plane. The first sub-stack 110A and the second sub-stack 110B may be separated from each other by the vertical structure VS and the insulating partition wall 147.

The first sub-stack 110A may include a plurality of first interlayer insulating patterns 111A and a plurality of first conductive patterns 113A which are arranged alternately with each other in the fourth direction DR4. The second sub-stack 110B may include a plurality of second interlayer insulating patterns 111B and a plurality of second conductive patterns 113B which are arranged alternately with each other in the fourth direction DR4.

The first interlayer insulating pattern 111A of the first sub-stack 110A may protrude toward the vertical structure VS more than the first conductive pattern 113A. As a result, a first lateral groove 110P1 may be defined in the first sub-stack 110A. The second interlayer insulating pattern 111B of the second sub-stack 110B may protrude toward the vertical structure VS more than the second conductive pattern 113B. As a result, a second lateral groove 110P2 may be defined in the second sub-stack 110B. The first lateral groove 110P1 and the second lateral groove 110P2 may have the same structure as described above with reference to FIGS. 5A to 5C.

The first conductive pattern 113A may include a side portion which is curved along the first lateral groove 110P1. The second conductive pattern 113B may include a side portion which is curved along the second lateral groove 110P2. As described above with reference to FIG. 10, the first data storage pattern 127A and the first blocking insulating pattern 120A may be disposed in the first lateral groove 110P1. The second data storage pattern 127B and the second blocking insulating pattern 120B may be arranged in the second lateral groove 110P2. As described above with reference to FIG. 10, each of the first blocking insulating pattern 120A and the second blocking insulating pattern 120B may include a first dielectric layer 121A or 121B, a second dielectric layer 123A or 123B, and a third dielectric layer 125A or 125B.

The vertical structure VS may include an insulating pillar 135, a first channel pattern 131A, a second channel pattern 131B, a first tunnel insulating pattern 129A, and a second tunnel insulating pattern 129B.

The insulating pillar 135 may include an outer wall which is convex in the second direction DR2 and the third direction DR3 opposing each other in the plane. The insulating pillar 135 may include a major axis which overlaps the center line L and a minor axis which crosses the center line L. According to an embodiment, the insulating pillar 135 may include a substantially elliptical cross-section. The insulating pillar 135 may extend toward an inner wall of the second channel pattern 131B from an inner wall of the first channel pattern 131A.

The first channel pattern 131A and the second channel pattern 131B may be separated from each other with the insulating pillar 135 interposed therebetween. The first channel pattern 131A and the second channel pattern 131B may be curved along the outer wall of the insulating pillar 135.

The first tunnel insulating pattern 129A and the second tunnel insulating pattern 129B may have the same material as described above with reference to FIG. 10 and may have the same structure as described above with reference to FIG. 10.

The insulating partition wall 147 may extend to be interposed between an end of the first channel pattern 131A and an end of the second channel pattern 131B from the insulating pillar 135. The insulating partition wall 147 may pass between the first blocking insulating pattern 120A and the second blocking insulating pattern 120B to separate each of the second dielectric layer and the third dielectric layer into the first pattern 121A, 123A, or 125A and the second pattern 121B, 123B, or 125B. The insulating partition wall 147 may be interposed between the first sub-stack 110A and the second sub-stack 110B between the insulating partition walls 135 adjacent to each other in the first direction DR1.

The insulating partition wall 147 may include the same or different material from the insulating pillar 135.

The first channel pattern 131A and the second channel pattern 131B may be connected to the first bit line 151A and the second bit line 151B as shown in FIG. 9A, respectively, or may be connected to the same bit line 151 as shown in FIG. 9B.

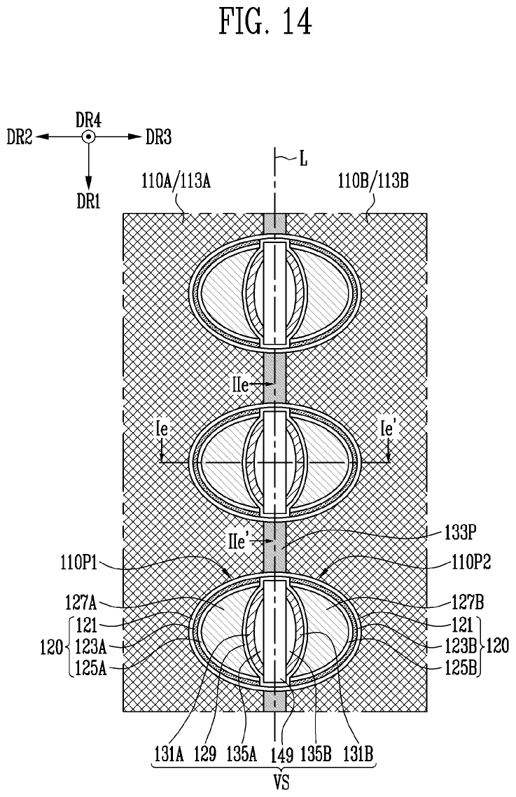

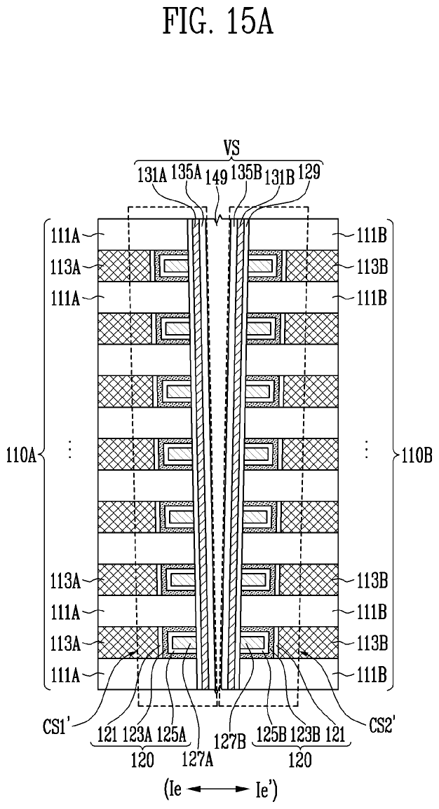

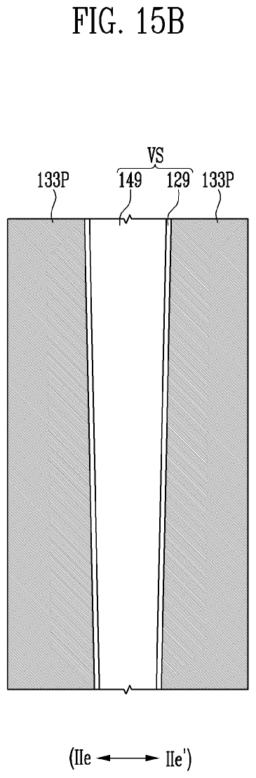

FIGS. 14, 15A, and 15B are diagrams illustrating a semiconductor memory device according to an embodiment of the present disclosure.

FIG. 14 is a plan view illustrating a semiconductor memory device. FIG. 15A is a cross-sectional diagram of a semiconductor memory device taken along line Ie-Ie′ of FIG. 14. FIG. 15B is a cross-sectional diagram illustrating a semiconductor memory device taken along line IIe-IIe′ of FIG. 14. Hereinafter, a description of the same configurations as those described with reference to FIGS. 9A, 9B, 10, 11A, and 11B is simplified or omitted.

Referring to FIGS. 14, 15A, and 15B, the semiconductor memory device may include a vertical structure VS, a first insulating partition wall 133P, a first sub-stack 110A, a second sub-stack 110B, a blocking insulating layer 120, a first data storage pattern 127A, and a second data storage pattern 127B.

The vertical structure VS may include a second insulating partition wall 149, a first channel pattern 131A, a second channel pattern 131B, a pillar pattern 135A or 135B, and a tunnel insulating layer 129. Each of the second insulating partition wall 149, the first channel pattern 131A, the second channel pattern 131B, the pillar pattern 135A or 135B, and the tunnel insulating layer 129 may extend in the fourth direction DR4.

The second insulating partition wall 149 may extend in the first direction DR1 and overlap a center line L which passes the center of the vertical structure VS. The second insulating partition wall 149 may be wider in the first direction DR1 than in the second direction DR2. The second insulating partition wall 149 may be arranged alternately with the first insulating partition wall 133P in the first direction DR1. The second insulating partition wall 149 may extend to be interposed between the end of the first channel pattern 131A and the end of the second channel pattern 131B.

The first channel pattern 131A and the second channel pattern 131B may be separated from each other with the second insulating partition wall 149 interposed therebetween. The pillar pattern 135A or 135B may be interposed between each of the first channel pattern 131A and the second channel pattern 131B and the second insulating partition wall 149. The pillar pattern 135A or 135B may include a side portion which is convex toward the channel pattern 131A or 131B corresponding thereto. The first channel pattern 131A and the second channel pattern 131B may be curved along a side portion of the pillar pattern 135A or 135B corresponding thereto.

The tunnel insulating layer 129 may surround the outer wall of each of the first channel pattern 131A and the second channel pattern 131B. The outer wall of the first channel pattern 131A may face the first conductive pattern 113A and the first interlayer insulating pattern 111A. The outer wall of the second channel pattern 131B may face the second conductive pattern 113B and the second interlayer insulating pattern 111B. According to an embodiment, the tunnel insulating layer 129 may extend between the first insulating partition wall 133P and the second insulating partition wall 149. However, embodiments of the present disclosure are not limited thereto. According to another embodiment, the second insulating partition wall 149 may extend toward the blocking insulating layer 120 so that the tunnel insulating layer 129 may be separated into the first tunnel insulating pattern and the second tunnel insulating pattern.

The first insulating partition wall 133P may be interposed between the first sub-stack 110A and the second sub-stack 110B between the vertical structures VS adjacent to each other in the first direction DR1. The first insulating partition wall 133P, the pillar pattern 135A or 135B, and the second insulating partition wall 149 may include the same or different materials.

The first sub-stack 110A may include a plurality of first interlayer insulating patterns 111A and a plurality of first conductive patterns 113A which are arranged alternately with each other in the fourth direction DR4. The second sub-stack 110B may include a plurality of second interlayer insulating patterns 111B and a plurality of second conductive patterns 113B which are arranged alternately with each other in the fourth direction DR4.

The first interlayer insulating pattern 111A of the first sub-stack 110A may protrude toward the vertical structure VS more than the first conductive pattern 113A. As a result, a first lateral groove 110P1 may be defined in the first sub-stack 110A. The second interlayer insulating pattern 111B of the second sub-stack 110B may protrude toward the vertical structure VS more than the second conductive pattern 113B. As a result, a second lateral groove 110P2 may be defined in the second sub-stack 110B. The first lateral groove 110P1 and the second lateral groove 110P2 may have the same structure as described above with reference to FIGS. 5A to 5C.

The first conductive pattern 113A may include a side portion which is curved along the first lateral groove 110P1. The second conductive pattern 113B may include a side portion which is curved along the second lateral groove 110P2. As described above with reference to FIG. 10, the first data storage pattern 127A may be disposed in the first lateral groove 110P1, and the second data storage pattern 127B may be disposed in the second lateral groove 110P2.

The blocking insulating layer 120 may extend along each of the inner wall of the first conductive pattern 113A toward the first channel pattern 131A and the inner wall of the second conductive pattern 113B toward the second channel pattern 131B. As described above with reference to FIGS. 5A to 5C, the blocking insulating layer 120 may include a first dielectric layer 121, a second dielectric layer 123A or 123B, and a third dielectric layer 125A or 125B. The first dielectric layer 121 may extend between the first insulating partition wall 133P and the second insulating partition wall 149. Each of the second and third dielectric layers may be separated into the first pattern 123A or 125A between the first conductive pattern 113A and the first data storage pattern 127A and the second pattern 123B or 125B between the second conductive pattern 113B and the second data storage pattern 127B. The tunnel insulating layer 129 may extend between the first pattern 123A or 125A and the second pattern 123B or 125B of each of the second dielectric layer and the third dielectric layer. However, embodiments of the present disclosure may not limited thereto. According to another embodiment, the second insulating partition wall 149 may extend to contact the first insulating partition wall 133P, so that the first dielectric layer 121 of the blocking insulating layer 120 may be separated into a first pattern and a second pattern.

The first channel pattern 131A and eh second channel pattern 131B may be connected to the first bit line 151A and the second bit line 151B as shown in FIG. 9A, respectively, or may be connected to the same bit line 151 as shown in FIG. 9B.

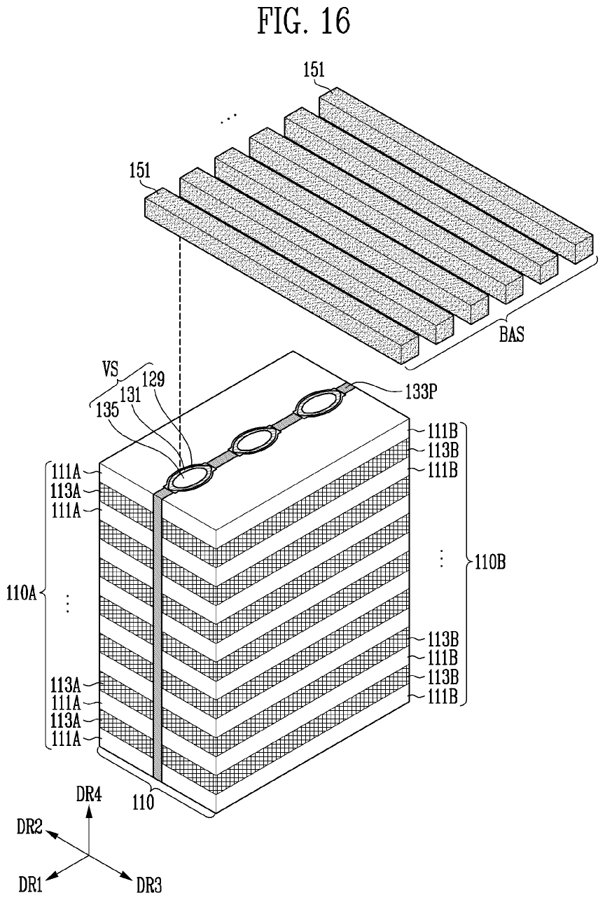

FIGS. 16, 17, 18A, and 18B are diagrams illustrating a semiconductor memory device according to an embodiment of the present disclosure.

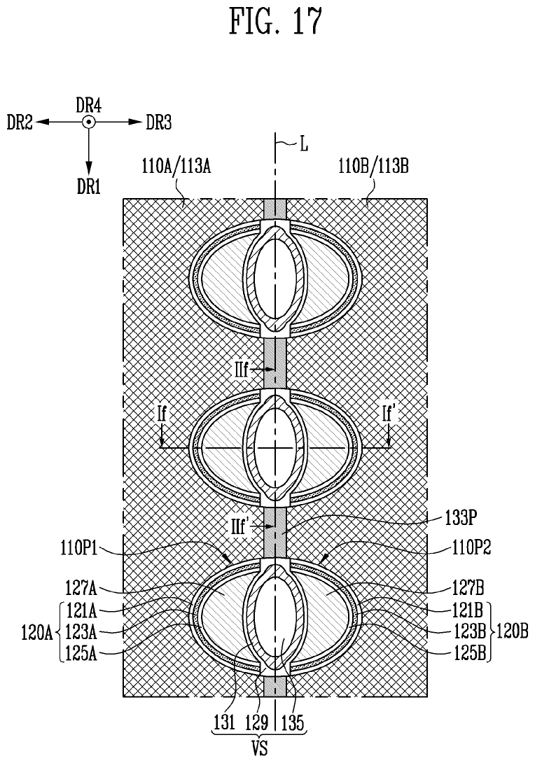

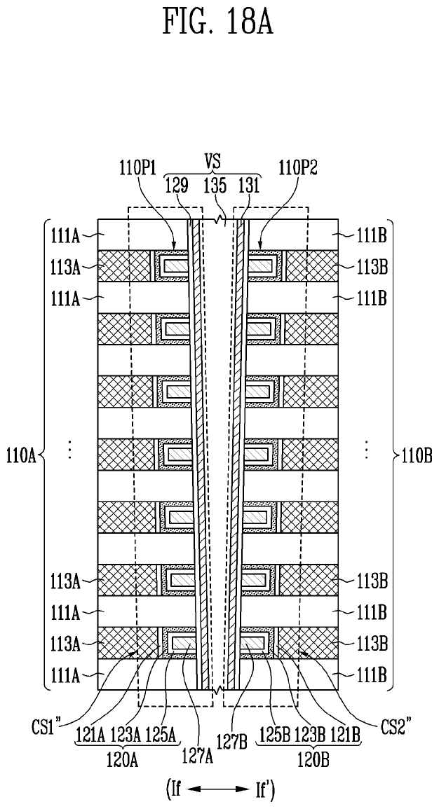

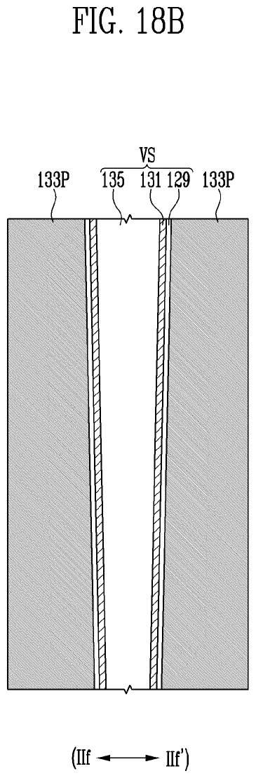

FIG. 16 is a perspective view illustrating a part of a semiconductor memory device. FIG. 17 is a plan view of a semiconductor memory device shown in FIG. 16. FIG. 18A is a cross-sectional diagram of a semiconductor memory device taken along line If-If′ of FIG. 17. FIG. 18B is a cross-sectional diagram illustrating a semiconductor memory device taken along line IIf-IIf′ of FIG. 17.

Referring to FIGS. 16, 17, 18A, and 17B, the semiconductor memory device may include a gate stack structure 110, a vertical structure VS, an insulating partition wall 133P, and a bit line array structure BAS.

The gate stack structure 110 may be divided by the slit SI shown in FIG. 4. The gate stack structure 110 may include a first sub-stack 110A and a second sub-stack 110B which are separated from each other. The first sub-stack 110A and the second sub-stack 110B may be separated from each other by the vertical structure VS and the insulating partition wall 133P.

The vertical structure VS and the insulating partition wall 133P may be alternately arranged with each other in the first direction DR1 on a center line L which extends in the first direction DR1 on a plane. The first sub-stack 110A may extend in the second direction DR2 from the vertical structure VS and the insulating partition wall 133P. The second sub-stack 110B may extend in the third direction DR3 from the vertical structure VS and the insulating partition wall 133P.

AS described above with reference to FIGS. 9A and 9B, the first sub-stack 110A may include a plurality of first interlayer insulating patterns 111A and a plurality of first conductive patterns 113A which are arranged alternately with each other in the fourth direction DR4, and the second sub-stack 110B may include a plurality of second interlayer insulating patterns 111B and a plurality of second conductive patterns 113B which are arranged alternately with each other in the fourth direction DR4.

The vertical structure VS may include an insulating pillar 135, a channel layer 131, and a tunnel insulating layer 129. The insulating pillar 135, the channel layer 131, and the tunnel insulating layer 129 of the vertical structure VS and the insulating partition wall 133P may extend in the fourth direction DR4 to pass between the plurality of first interlayer insulating patterns 111A and the plurality of second interlayer insulating patterns 111B and between the plurality of first conductive patterns 113A and the plurality of second conductive patterns 113B.

The insulating pillar 135 may be convex toward the second direction DR2 and the third direction DR3 with respect to the center line L. In a plan view, the insulating pillar 135 may have an elliptical shape and the center line L may overlap the major axis of the insulating pillar 135.

The channel layer 131 may be continuously extended along the outer wall of the insulating pillar 135 to surround the outer wall of the insulating pillar 135. According to an embodiment, the channel layer 131 may have substantially a tubular shape. The insulating pillar 135 may be arranged at the central area of the channel layer 131 having the substantially tubular shape. The channel layer 131 having the substantially tubular shape may extend between the insulating partition wall 133P and the insulating pillar 135. The channel layer 131 may include the same material as the first channel pattern 131A and the second channel pattern 131B as shown in FIG. 4.

The tunnel insulating layer 129 may be continuously extended along the outer wall of the channel layer 131 to surround the outer wall of the channel layer 131. In an embodiment, the insulating pillar 135 may be located at a central area of the tunnel insulating layer 129 including the substantially tubular shape. The tunnel insulating layer 129 having the substantially tubular shape may extend between the insulating partition wall 133P and the channel layer 131. The tunnel insulating layer 129 may include the same material as described above with reference to FIGS. 5A to 5C.

The first conductive pattern 113A of the first sub-stack 110A and the second conductive pattern 113B of the second sub-stack 110B may extend in the second direction DR2 and the third direction DR3 opposing each other with respect to the center line L. The first interlayer insulating pattern 111A of the first sub-stack 110A and the second interlayer insulating pattern 111B of the second sub-stack 110B may extend in the second direction DR2 and the third direction DR3 opposing each other with respect to the center line L.

The first interlayer insulating pattern 111A of the first sub-stack 110A may protrude toward the vertical structure VS more than the first conductive pattern 113A. As a result, a first lateral groove 110P1 may be defined in the first sub-stack 110A. The second interlayer insulating pattern 111B of the second sub-stack 110B may protrude toward the vertical structure VS more than the second conductive pattern 113B. As a result, a second lateral groove 110P2 may be defined in the second sub-stack 110B. The first lateral groove 110P1 and the second lateral groove 110P2 may have the same structure as described above with reference to FIGS. 5A to 5C.

The first conductive pattern 113A may include a side portion which is curved along the first lateral groove 110P1. The second conductive pattern 113B may include a side portion which is curved along the second lateral groove 110P2. The first data storage pattern 127A may be disposed in the first lateral groove 110P1. The second data storage pattern 127B may be disposed in the second lateral groove 110P2.

Each of the first data storage pattern 127A and the second data storage pattern 127B may have a shape corresponding to that of the lateral groove corresponding thereto. According to an embodiment, the distance between the first channel pattern 131A and the first conductive pattern 113A and the distance between the second channel pattern 131B and the second channel pattern 131B and the second conductive pattern 113B may decrease toward the center line L. For example, in an embodiment, a variable distance between the first channel pattern 131A and the first conductive pattern 113A decreases with decreasing distance of the first channel pattern 131A and the first conductive pattern 113A from the center line L. For example, in an embodiment, a variable distance between the second channel pattern 131B and the second conductive pattern 113B decreases with decreasing distance of the second channel pattern 131B and the second conductive pattern 113B from the center line L. In response, the width of each of the first lateral groove 110P1 and the second lateral groove 110P2 may decrease toward the center line L in the plane. Accordingly, the width of each of the first data storage pattern 127A and the second data storage pattern 127B may decrease toward the center line L. The first data storage pattern 127A and the second data storage pattern 127B may include the materials which are described above with reference to FIGS. 5A to 5C.

The first blocking insulating pattern 120A may extend along the inner wall of the first conductive pattern 113A. The second blocking insulating pattern 120B may extend along the inner wall of the second conductive pattern 113B. The inner wall of each of the first conductive pattern 113A and the second conductive pattern 113B may face the channel layer 131. Each of the first blocking insulating pattern 120A and the second blocking insulating pattern 120B may include a first dielectric layer 121A or 121B, a second dielectric layer 123A or 123B, and a third dielectric layer 125A or 125B. Each of the first dielectric layer, the second dielectric layer, and the third dielectric layer may be separated into the first pattern 121A, 123A, or 125A and the second pattern 121B, 123B, or 125B by the tunnel insulating layer 129. The first dielectric layer 121A or 121B, the second dielectric layer 123A or 123B, and the third dielectric layer 125A or 125B may include the materials as described above with reference to FIGS. 5A to 5C.

The bit line array structure BAS may include a plurality of bit lines 151. Each of the bit lines 151 may be connected to the channel layer 131 corresponding thereto.

A first portion of the channel layer 131 toward the first sub-stack 110A may serve as a channel region of a first memory cell string CS1″. A second portion of the channel layer 131 toward the second sub-stack 110B may serve as a channel region of a second memory cell string CS2″. The plurality of first conductive patterns 113A which control the first memory cell string CS1″ may be separated from the plurality of second conductive patterns 113B which control the second memory cell string CS2″ by the connection between the vertical structure VS and the insulating partition wall 133P. As a result, the first memory cell string CS1″ and the second memory cell string CS2″ which are connected to the same channel layer 131 may be controlled by the first conductive pattern 113A and the second conductive pattern 113B, respectively, which are separated from each other.

The data storage pattern 123A or 123B according to the embodiments as described above with reference to FIGS. 4 to 18B may be disposed in the lateral groove 110P1 or 110P2. The lateral groove 110P1 or 110P2 may be separated in the fourth direction DR4 corresponding to a vertical direction. From a plan view, the width of the lateral groove 110P1 or 110P2 may decrease to the end.

Hereinafter, various embodiments of a method of manufacturing the semiconductor memory device which includes the above-described lateral groove 110P1 or 110P2 will be described below.

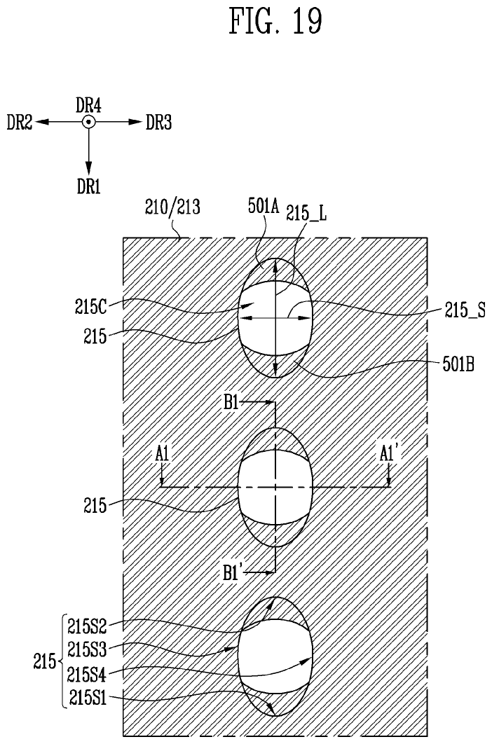

FIGS. 19, 20A, 20B, 21, 22A, 22B, 23, 24A, 24B, 25, 26A, 26B, 27, 28, 29, 30, 31, 32A, 32B, 33, 34A, 34B, 35A, and 35B are diagrams illustrating a method of manufacturing a semiconductor memory device according to an embodiment of the present disclosure.

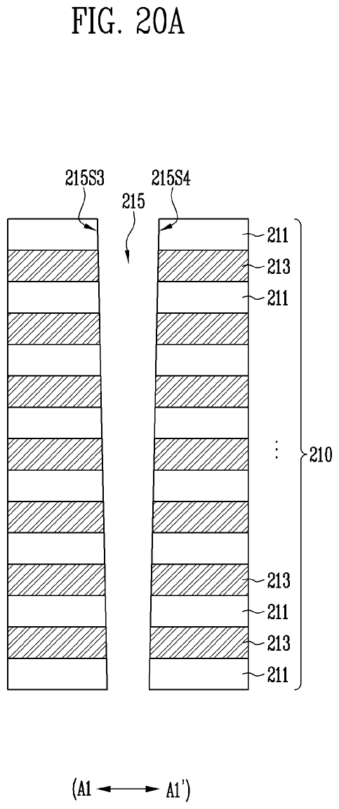

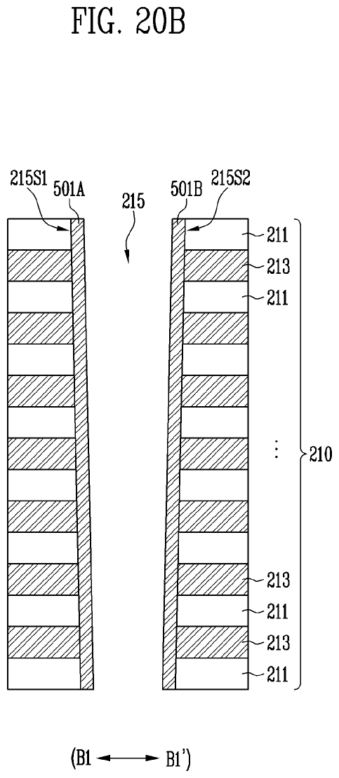

FIGS. 19, 21, 23, 25, 27, 29, 31 and 33 are plan views illustrating process for manufacturing a semiconductor memory device. FIGS. 20A, 22A, 24A, 26A, 28, 30, 32A, 34A and 35A are cross-sectional diagrams taken along line A′-A1′ of the corresponding plan views, respectively. FIGS. 20B, 22B, 24B, 26B, 32B, 34B, and 35B are cross-sectional diagrams taken along line B′-B1′ of the corresponding plan views, respectively.

FIGS. 19, 20A, and 20B are diagrams illustrating processes of forming a preliminary stack structure 210 through which a plurality of holes 215 are formed.

Referring to FIGS. 19, 20A, and 20B, the preliminary stack structure 210 may be formed on a lower structure (not shown). According to an embodiment, the lower structure may be a sacrificial substrate which includes a silicon wafer. The sacrificial substrate may be replaced by a doped semiconductor structure during subsequent processes. According to another embodiment, the lower structure may include a structure which includes a peripheral circuit and a doped semiconductor structure.

The preliminary stack structure 210 may be formed on a lower structure according to the above-described various embodiments. The preliminary stack structure 210 may be penetrated by the plurality of holes 215. From a plan view, a cross-section of each hole 215 may include a major axis 215_L in the first direction DR1 and a minor axis 215_S in the third direction DR3. According to an embodiment, the cross-section of the hole 215 may have a substantially elliptical shape.

The preliminary stack structure 210 may include a plurality of first material layers 211 and a plurality of second material layers 213 that are stacked alternately with each other in the fourth direction DR4. The plurality of second material layers 213 may have a material having an etch selectivity with respect to the plurality of first material layers 211. According to an embodiment, the plurality of first material layers 211 may include an insulating material such as a silicon oxide layer, and the plurality of second material layers 213 may include a sacrificial insulating material such as a silicon nitride layer.

Forming the hole 215 may include forming a mask pattern (not shown) which defines a cross-sectional surface of the hole 215 on the preliminary stack structure 210 and etching the plurality of first material layers 211 and the plurality of second material layers 213 by using a mask pattern as an etch barrier. After the hole 215 is formed, the mask pattern may be removed. The hole 215 may extend in the fourth direction DR4 to pass through the plurality of first material layers 211 and the plurality of second material layers 213.

The hole 215 may include first to fourth inner walls 215S1 to 215S4. The first inner wall 215S1 and the second inner wall 215S2 of the hole 215 may be aligned on the major axis 215_L of the hole 215 and face each other in the first direction DR1. The third inner wall 215S3 and the fourth inner wall 215S4 of the hole 215 may be aligned on the minor axis 215_S of the hole 215 and may face each other in the second direction DR2 or the third direction DR3.

Subsequently, a first etch barrier pattern 501A and a second etch barrier pattern 501B may be formed to partially block a side portion of each of the plurality of first material layers 211 and the plurality of second material layers 213 exposed through the hole 215. The first etch barrier pattern 501A and the second etch barrier pattern 501B may be formed using an etch barrier layer which includes substantially the same material as the plurality of second material layers 213.

The processes of forming the first etch barrier pattern 501A and the second etch barrier pattern 501B may include a process of forming an etch barrier layer along the hole 215 and a process of removing a portion of the etch barrier layer through an etch process to separate the etch barrier layer into the first etch barrier pattern 501A and the second etch barrier layer 501B. Though not shown, the etch barrier layer may extend continuously along the first to fourth inner walls 215S1 to 215S4 of the hole 215 so that a central region of the etch barrier layer may have an open tubular shape. An elliptical opening which is smaller than the elliptical shape defined by the hole 215 may be defined by an inner wall of the etch barrier layer having the tubular shape. When a portion of the etch barrier layer is removed, isotropic etching may be performed on the etch barrier layer toward the first to fourth inner walls 215S1 to 215S4 of the hole 215 from the elliptical opening defined by the inner wall of the etch barrier layer. Isotropic etching may be performed by at least one of wet etching and dry etching. An area of the inner wall of the etch barrier layer which is exposed by an etching material may vary depending on each area by the shape of the elliptical opening defined by the inner wall of the etch barrier layer. As a result, the closer it gets to the minor axis of the elliptical opening, the faster the etching operation may be performed from the inner wall of the etch barrier layer toward the first to fourth inner walls 215S1 to 215S4.

The third inner wall 215S3 and the fourth inner wall 215S4 of the hole 215 may be exposed using the above-described isotropic etching. A portion of the etch barrier layer may remain as the first etch barrier pattern 501A and the second etch barrier pattern 501B to block the first inner wall 215S1 and the second inner wall 21552 of the hole 215. A width of each of the remaining first and second etch barrier patterns 501A and 501B may decrease toward the minor axis 215_S of the hole 215.

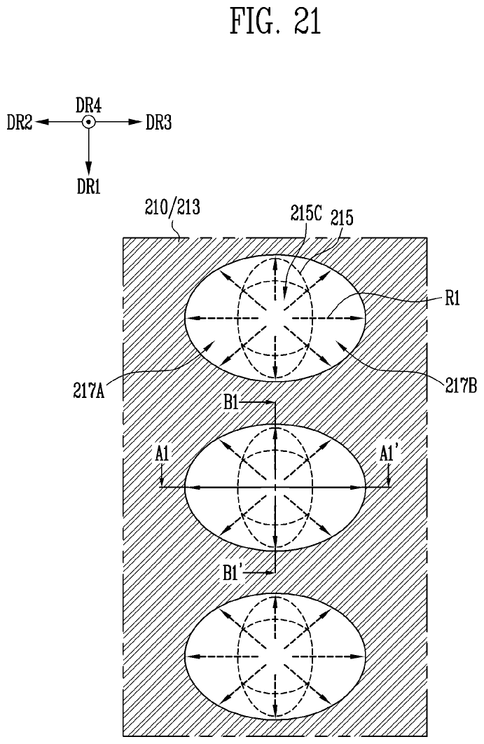

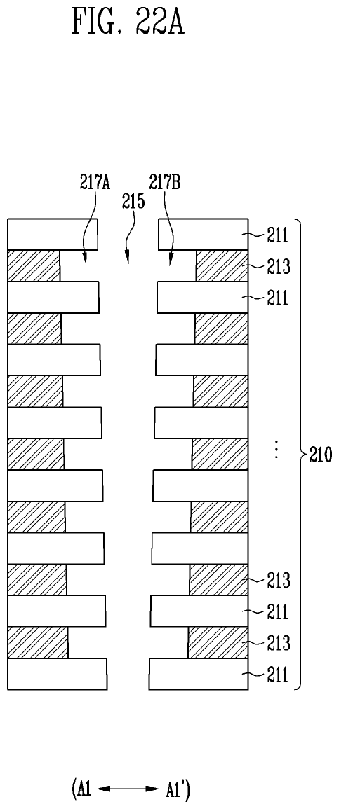

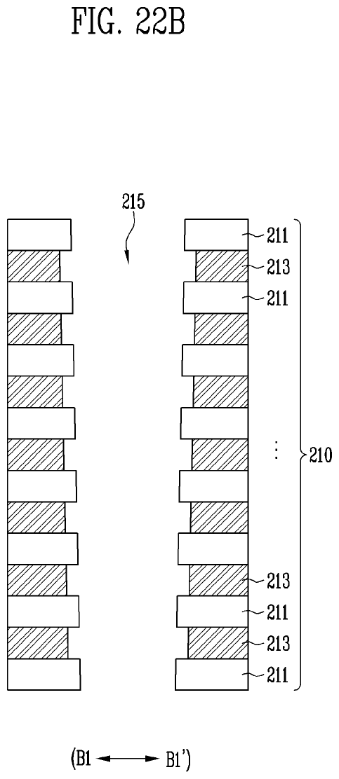

FIGS. 21, 22A, and 22B are diagrams illustrating processes of forming a first lateral groove 217A and a second lateral groove 217B.

Referring to FIGS. 21, 22A, and 22B, isotropic etching may be performed on a portion of each of the plurality of second material layers 213 which are exposed through the third inner wall 215S3 and the fourth inner wall 215S4 of the hole 215 as shown in FIG. 19. As a result, the first lateral groove 217A and the second lateral groove 217B may be formed in the side portion of the preliminary stack structure 210. The first lateral groove 217A and the second lateral groove 217B may be adjacent to each other in the second direction DR2 or the third direction DR3. Each of the first lateral groove 217A and the second lateral groove 217B be disposed between two first material layers which are adjacent to each other in the fourth direction DR4 among the plurality of first material layers 211.

Isotropic etching may be performed by at least one of wet etching and dry etching. An etching material for isotropic etching may be introduced along a route R1 from a central area 215C of the hole 215 which is opened by the first etch barrier pattern 501A and the second etch barrier pattern 501B as shown in FIG. 19. When isotropic etching is performed, the first etch barrier pattern 501A and the second etch barrier pattern 501B, which include substantially the same material as the plurality of second material layers 213, as shown in FIG. 19 may be removed. As a result, the first inner wall 215S1 and the second inner wall 215S2 of the hole 215 may be exposed.

A portion of each of the plurality of second material layers 213 which are adjacent to the first inner wall 215S1 and the second inner wall 215S2 of the hole 215 as shown in FIG. 19 may be protected by the first etch barrier pattern 501A and the second etch barrier pattern 501B. Therefore, even when the first etch barrier pattern 501A and the second etch barrier pattern 501B are removed by isotropic etching for forming the first etch barrier pattern 501A and the second etch barrier pattern 501B, and a portion of each of the first inner wall 215S1 and the second inner wall 215S2 of the hole 215 shown in FIG. 19 is exposed and etched, an etching amount thereof may be much smaller than that in the second direction DR2 and the third direction DR3.

By the above-described processes, the first lateral groove 217A and the second lateral groove 217B which decrease in width toward the first inner wall 215S1 and the second inner wall 215S2 of FIG. 19 may be defined.

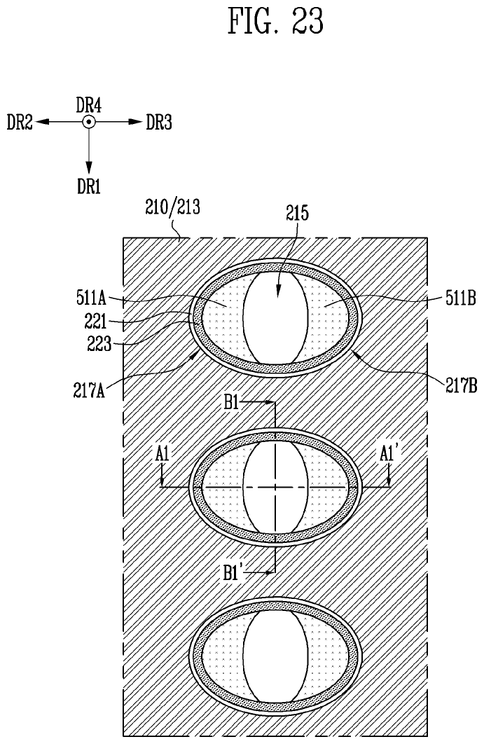

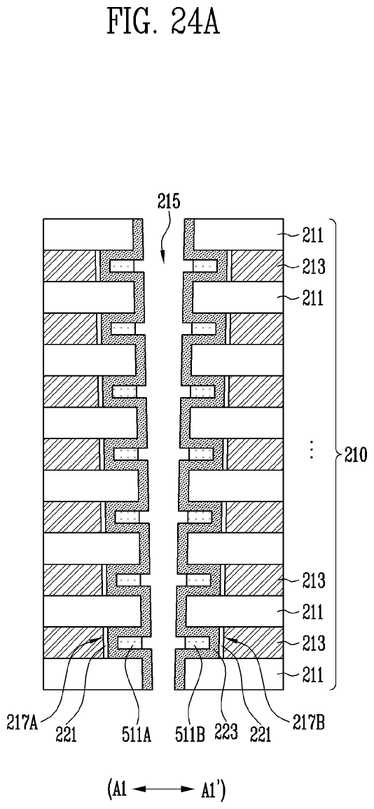

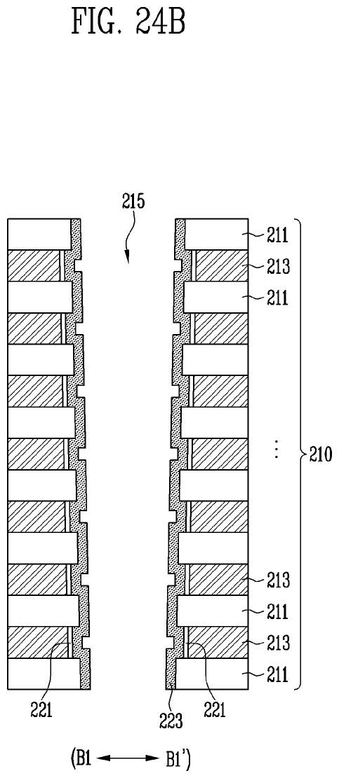

FIGS. 23, 24A, and 24B are diagrams illustrating processes of forming a first dielectric layer 221 and a second dielectric layer 223.

Referring to FIGS. 23, 24A, and 24B, a side portion of each of the plurality of second material layers 213 which are exposed through the hole 215, the first lateral groove 217A and the second lateral groove 217B may be formed. As a result, the first dielectric layer 221 may be formed in each of the plurality of second material layers 213 toward the hole 215.

Subsequently, the second dielectric layer 223 may be formed on the surface of the first dielectric layer 221. The second dielectric layer 223 may extend along the surface of each of the first lateral groove 217A, the second lateral groove 217B, and the hole 215. The second dielectric layer 223 may include a nitride layer such as a silicon nitride layer.

Subsequently, a first mask pattern 511A and a second mask pattern 511B may be formed at a central region of the first lateral groove 217A and a central region of the second lateral groove 217B, respectively, which are opened by the second dielectric layer 223. The first mask pattern 511A and the second mask pattern 511B may include a material having an etch selectivity with respect to the first dielectric layer 221 and the second dielectric layer 223. According to an embodiment, each of the first mask pattern 511A and the second mask pattern 511B may include a silicon layer. The first mask pattern 511A and the second mask pattern 511B may be separated from each other with the hole 215 interposed therebetween. A portion of the second dielectric layer 223 may be exposed between the first mask pattern 511A and the second mask pattern 511B.

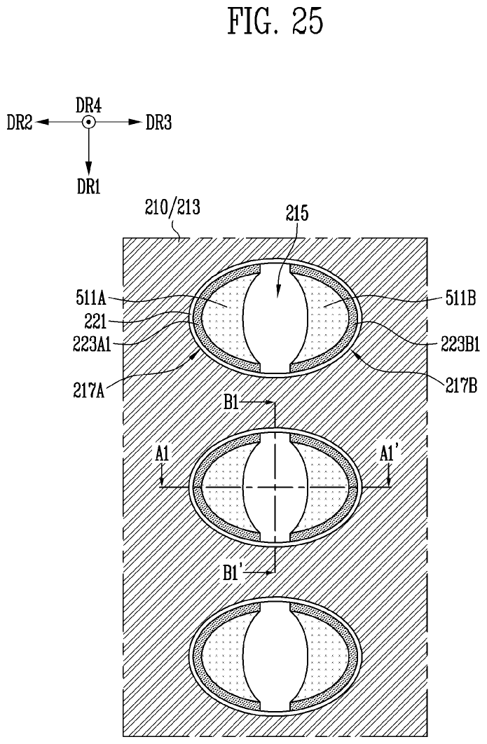

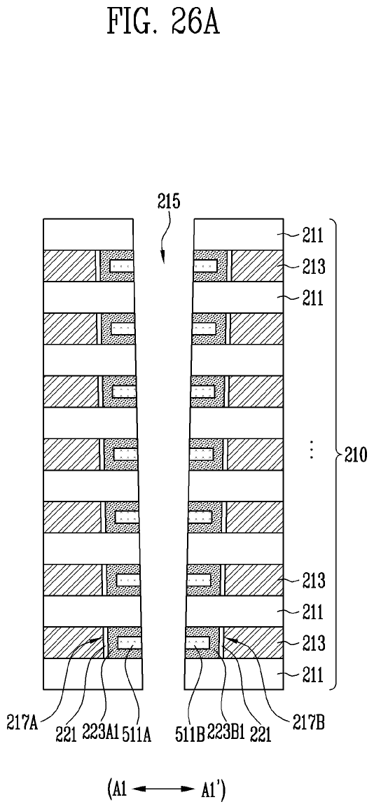

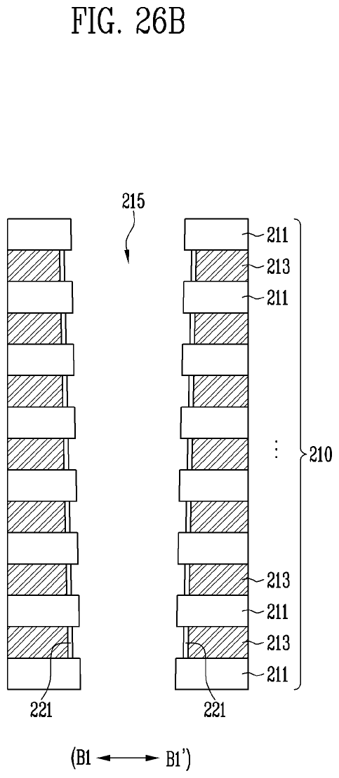

FIGS. 25, 26A, and 26B are diagrams illustrating processes of separating the second dielectric layer into a first preliminary pattern 223A1 and a second preliminary pattern 223B1.

Referring to FIGS. 25, 26A, and 26B, a portion of the exposed second dielectric layer may be removed by an etch process using the first mask pattern 511A and the second mask pattern 511B as an etch barrier. As a result, the second dielectric layer may be separated into the first preliminary pattern 223A1 and the second preliminary pattern 223B1. The first dielectric layer 221 may be exposed between the first preliminary pattern 223A1 and the second preliminary pattern 223B1.

Subsequently, inner walls of the first preliminary pattern 223A1 and the second preliminary pattern 223B1 may be exposed by selectively removing the first mask pattern 511A and the second mask pattern 511B.

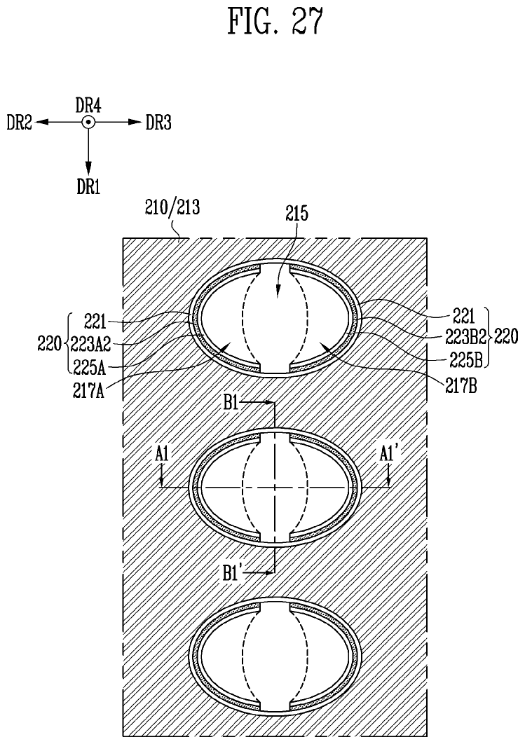

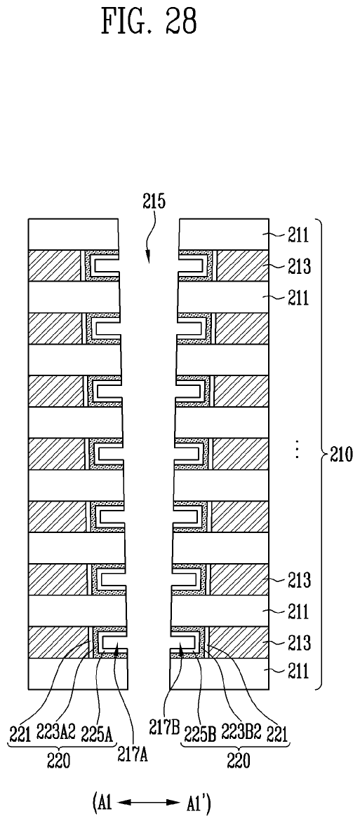

FIGS. 27 and 28 are diagrams illustrating processes of forming a first pattern 225A and a second pattern 225B of a third dielectric layer.

Referring to FIGS. 27 and 28, after the inner walls of the first preliminary pattern 223A1 and the second preliminary pattern 223B1 shown in FIGS. 25, 26A, and 26B are exposed, portions thereof may be oxidized. Non-oxidized regions of the first preliminary pattern 223A1 and the second preliminary pattern 223B1 may remain as a first pattern 223A2 and a second pattern 223B2 of the second dielectric layer. Oxidized regions of the first preliminary pattern 223A1 and the second preliminary pattern 223B1 may form the first pattern 225A and the second pattern 225B of the third dielectric layer. The first pattern 225A and the second pattern 225B of the third dielectric layer may include an oxide layer such as a silicon oxynitride layer.

The first dielectric layer 221, the first pattern 223A2 and the second pattern 223B2 of the second dielectric layer, and the first pattern 225A and the second pattern 225B of the third dielectric layer may form a blocking insulating layer 220. Through the above-described processes, the blocking insulating layer 220 may be formed on a layer on which each of the plurality of second material layers 213 is arranged, and may be excluded from the layer on which each of the plurality of first material layers 211 is formed. An inner wall of the blocking insulating layer 220 may be exposed in the first lateral groove 217A and the second lateral groove 217B.

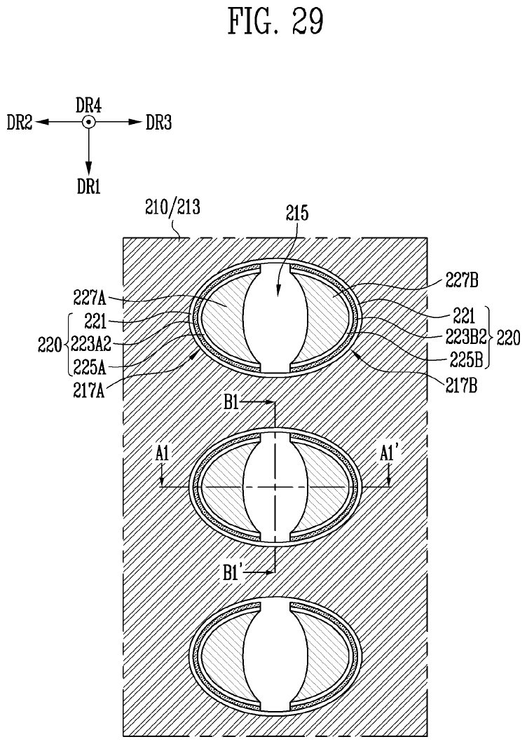

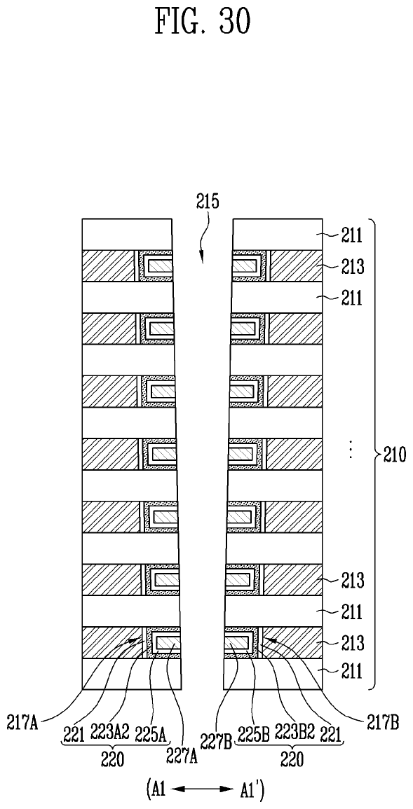

FIGS. 29 and 30 are diagrams illustrating processes of forming a first data storage pattern 227A and a second data storage pattern 227B.

Referring to FIGS. 29 and 30, the first data storage pattern 227A and the second data storage pattern 227B may be formed on the exposed inner wall of the blocking insulating layer 220. The processes of forming the first data storage pattern 227A and the second data storage pattern 227B may include a process of forming a data storage layer to fill the first lateral groove 217A and the second lateral groove 217B and a process of removing a portion of the data storage layer such that the data storage layer may be separated into the first data storage pattern 227A and the second data storage pattern 227B. The first data storage pattern 227A may be disposed in the first lateral groove 217A. The second data storage pattern 227B may be disposed in the second lateral groove 217B.

According to an embodiment, the data storage layer may include a charge trap insulating layer, a floating gate layer, and an insulating layer including conductive nanodots. The charge trap insulating layer may include a silicon nitride layer. The floating gate layer may include a silicon layer. However, the present disclosure is not limited thereto. According to another embodiment, the data storage layer may include a phase-change material layer, a ferroelectric layer, or the like.

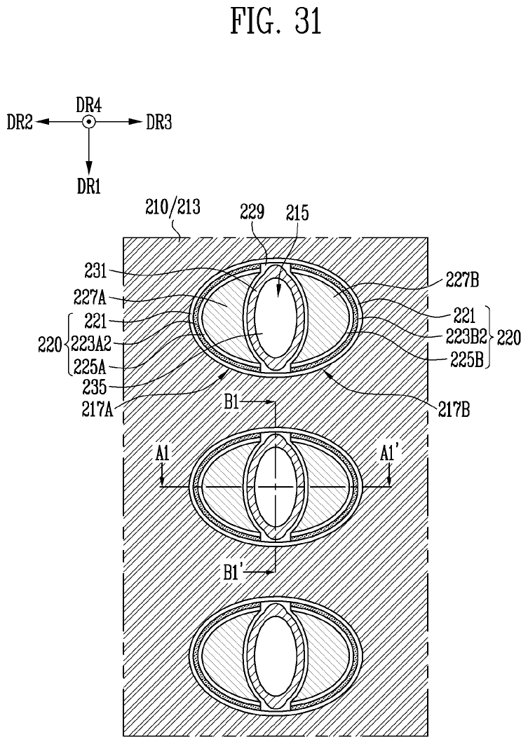

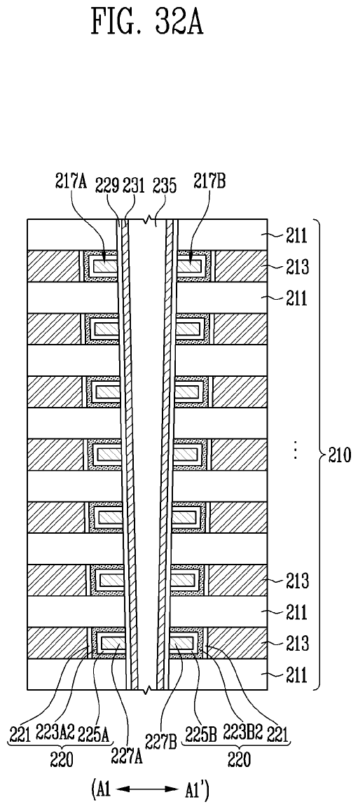

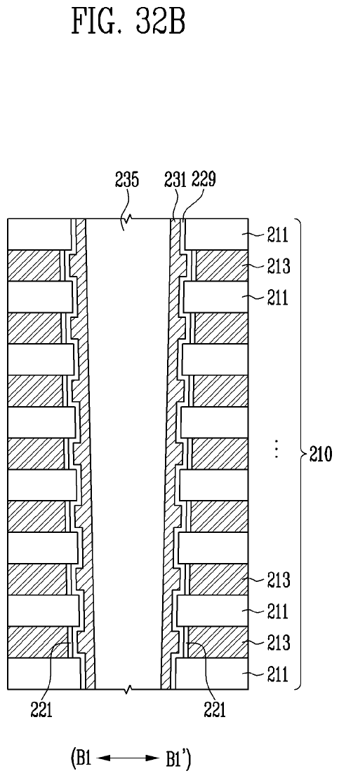

FIGS. 31, 32A, and 32B are diagrams illustrating processes of forming a preliminary vertical structure.

Referring to FIGS. 31, 32A, and 32B, a tunnel insulating layer 229 may be formed along an inner wall of each of the first data storage pattern 227A and the second data storage pattern 227B. The tunnel insulating layer 229 may extend along a sidewall of the hole 215 between the first data storage pattern 227A and the second data storage pattern 227B.

The tunnel insulating layer 229 may extend to cover the first dielectric layer 221 of the blocking insulating layer 220 which is opened between the first data storage pattern 227A and the second data storage pattern 227B and may have substantially a tubular shape. The tunnel insulating layer 229 may extend to be interposed between the first pattern 225A and the second pattern 225B of the third dielectric layer and between the first pattern 223A2 and the second pattern 223B2 of the third dielectric layer.

The tunnel insulating layer 229 may include an oxide layer such as a silicon oxide layer.

Subsequently, a channel layer 231 may be formed along an inner wall of the tunnel insulating layer 229. The channel layer 231 may include silicon (Si), germanium (Ge), or a mixture thereof.

The channel layer 231 may have substantially a tubular shape such that a central region of the hole 215 may be opened.

Subsequently, the central region of the hole 215 opened by the channel layer 231 may be filled with an insulating material to thereby form an insulating pillar 235. As a result, a preliminary vertical structure which includes the tunnel insulating layer 229, the channel layer 231, and the insulating pillar 235 may be formed. Each of the tunnel insulating layer 229, the channel layer 231, and the insulating pillar 235 may extend in the fourth direction DR4 along the hole 215.

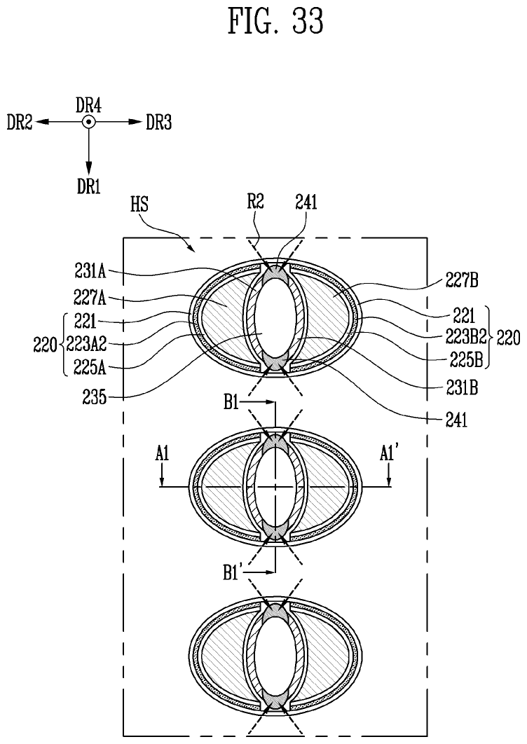

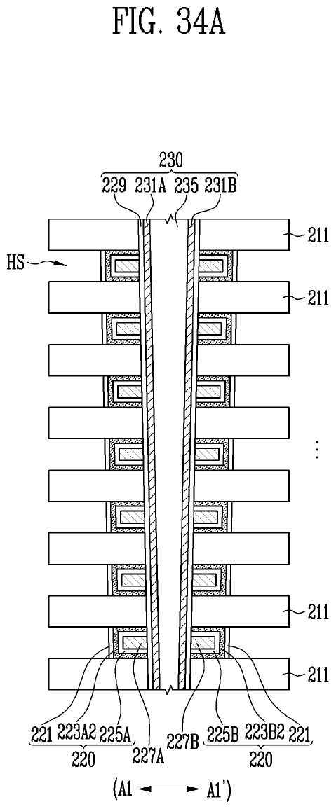

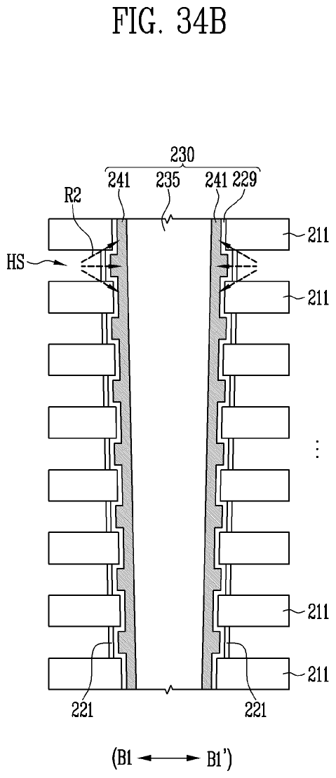

FIGS. 33, 34A, and 34B are diagrams illustrating processes of forming a semiconductor oxide layer 241.

Referring to FIGS. 33, 34A, and 34B, the slit SI shown in FIG. 4 may be formed. The slit SI shown in FIG. 4 may extend in the fourth direction DR4 to pass through the plurality of first material layers 211 and the plurality of second material layers 213 shown in FIGS. 32A and 32B. The second material layers 213 shown in FIGS. 32A and 32B may be removed through the slit SI. As a result, a plurality of horizontal spaces HS may be opened between the plurality of first material layers 211.

Subsequently, a portion of the channel layer 231 as shown in FIGS. 31, 32A, and 32B may be selectively oxidized through the plurality of horizontal spaces HS. Selective oxidation may be performed by a wet etch process. However, the first pattern 223A2 and the second pattern 223B2 of the second dielectric layer which includes a nitride layer such as a silicon nitride layer may hardly be oxidized, and may serve as a barrier of the wet oxidation process. As a result, another portion of the channel layer 231 which is protected by the first pattern 223A2 and the second pattern 223B2 of the second dielectric layer may remain as a first channel pattern 231A and a second channel pattern 231B. An oxidized region of the channel layer may remain as the semiconductor oxide layer 241. The semiconductor oxide layer 241 may be formed when a portion of the channel layer 231 is selectively oxidized by a wet oxidation process which is performed through a route R2 as indicated by a dotted line. The first channel pattern 231A and the second channel pattern 231B may be separated from each other by the semiconductor oxide layer 241.

Through the above-described processes, the vertical structure which includes the tunnel insulating layer 229, a first channel pattern 231A, the second channel pattern 231B, the insulating pillar 235, and the semiconductor oxide layer 241 may be defined.

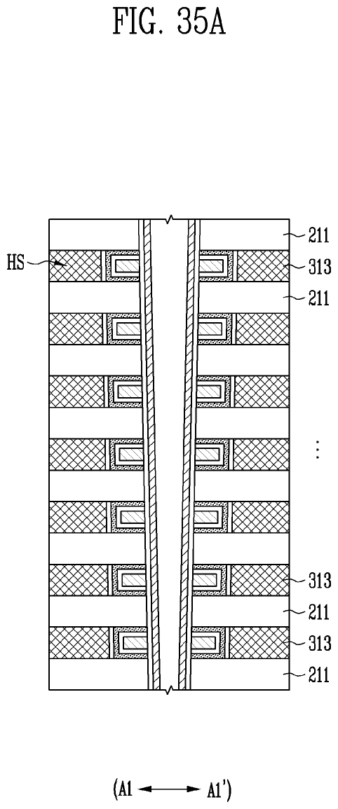

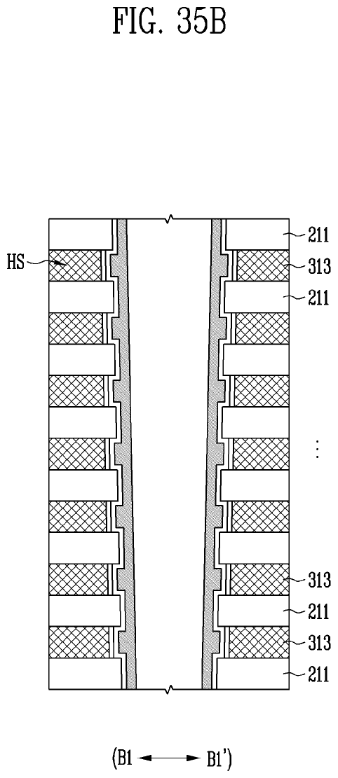

FIGS. 35A and 35B are diagrams illustrating processes of forming a plurality of third material layers 313.

Referring to FIGS. 35A and 35B, the plurality of third material layers 313 may be formed in the plurality of horizontal spaces HS, respectively. Each of the third material layers 313 may include at least one of a doped semiconductor layer, a metal layer, and a conductive metal nitride layer.

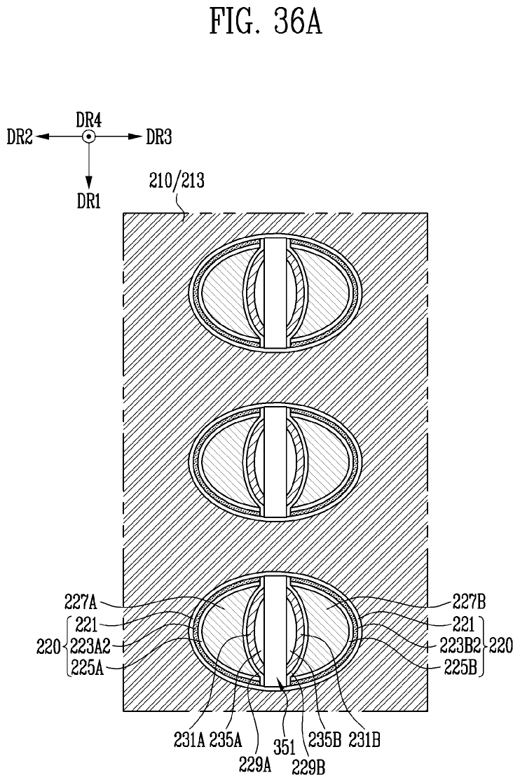

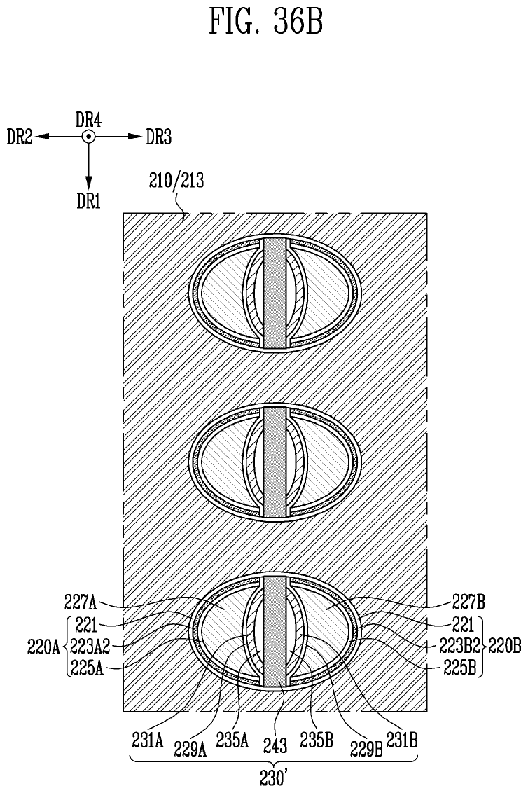

FIGS. 36A and 36B are diagrams illustrating a method of manufacturing a semiconductor memory device according to embodiments of the present disclosure.

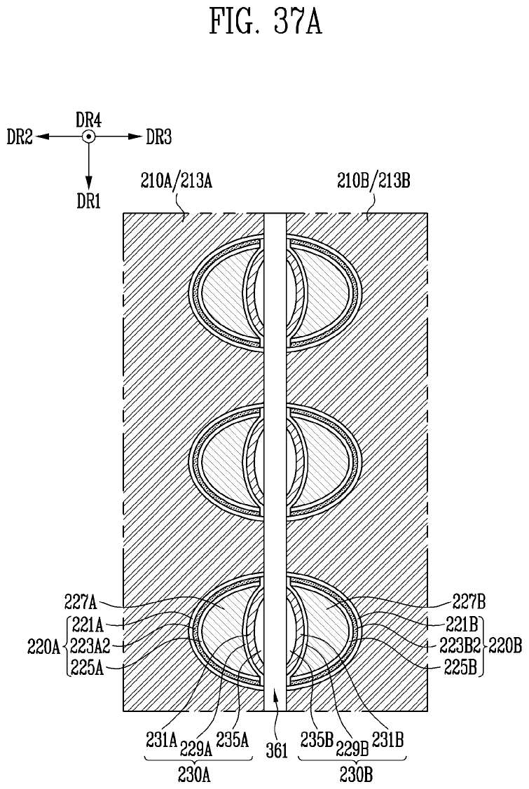

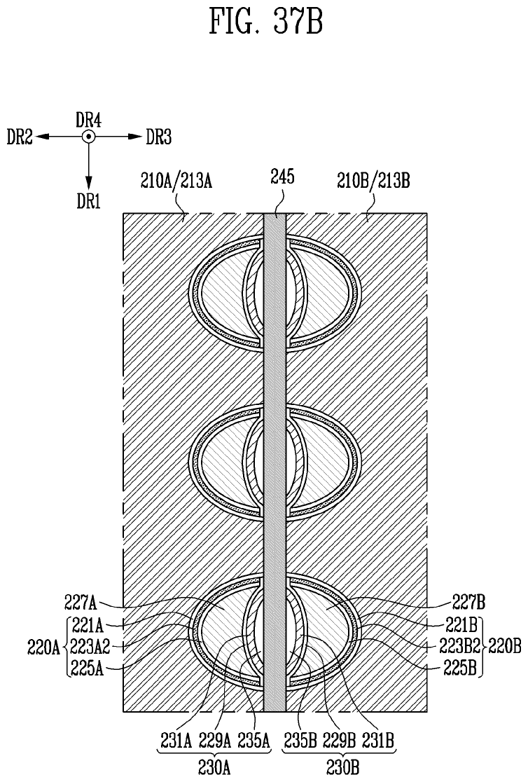

FIGS. 37A and 37B are diagrams illustrating a method of manufacturing a semiconductor memory device according to embodiments of the present disclosure.

Hereinafter, a description of the same processes as described in FIGS. 19 to 35B will be simplified or omitted.

Before the processes of FIG. 36A or 37A are performed, the processes as described above with reference to FIGS. 19 to 32B may be performed. Therefore, as shown in FIGS. 31, 32A, and 32B, the preliminary stack structure 210 which is penetrated by a hole 315 includes the first lateral groove 217A and the second lateral groove 217B, and includes the plurality of first material layers 211 and the plurality of second material layers 213 stacked alternately with each other may be provided. A preliminary vertical structure which includes the tunnel insulating layer 229, the channel layer 231, and the insulating pillar 235 may be formed in the hole 215. The blocking insulating layer 220 may be formed along the inner walls of the first lateral groove 217A and the second lateral groove 217B. The first data storage pattern 227A may be disposed in the first lateral groove 217A, and the second data storage pattern 227B may be disposed in the second lateral groove 217B. The blocking insulating layer 220 may include the first dielectric layer 221, the first pattern 223A2 and the second pattern 223B2 of the second dielectric layer, and the first pattern 225A and the second pattern 225B of the third dielectric layer.

Thereafter, as shown in FIG. 36A, a trench 351 may be formed. After a mask pattern (not shown) which defines the trench 351 is formed, the insulating pillar 235 and the channel layer 231 as shown in FIGS. 31, 32A, and 32B may be etched through an etch process using the mask pattern as an etch barrier to thereby form the trench 351. The trench 351 may overlap the center of the insulating pillar 235 as shown in FIGS. 31, 32A, and 32B and may extend in the first direction DR1 to pass through the channel layer 231 as shown in FIGS. 31, 32A, and 32B. As a result, the insulating pillar 235 shown in FIGS. 31, 32A, and 32B may be separated into a first insulating pillar 235A and a second pillar pattern 235B by the trench 351. In addition, the channel layer 231 shown in FIGS. 31, 32A, and 32B may be separated into the first channel pattern 231A and the second channel pattern 231B by the trench 351.

A length of the trench 351 in the first direction DR1 may be controlled such that the channel layer 231 shown in FIGS. 31, 32A, and 32B may be separated into the first channel pattern 231A and the second channel pattern 231B. According to an embodiment, the length of the trench 351 may be controlled to expose the inner wall of the tunnel insulating layer 229 shown in FIGS. 31, 32A, and 32B. According to another embodiment, the length of the trench 351 may be controlled so that the tunnel insulating layer 229 shown in FIGS. 31, 32A, and 32B may be separated into a first tunnel insulating pattern 229A and a second tunnel insulating pattern 229B. According to another embodiment, the length of the trench 351 may be controlled so that the first dielectric layer 221 of the blocking insulating layer 220 may be separated into a first pattern and a second pattern.

Referring to FIG. 36B, the trench 351 shown in FIG. 36A may be filled with an insulating material to form an insulating partition wall 243. As a result, a vertical structure 230′ which includes the insulating partition wall 243, a first pillar pattern 235A, a second pillar pattern 235B, the first channel pattern 231A, the second channel pattern 231B, the first tunnel insulating pattern 229A, and the second tunnel insulating pattern 229B may be formed.

After the vertical structure 230′ is formed, the slit SI as described with reference to FIG. 4 may be formed. The second material layer 213 as shown in FIG. 36B may include a sacrificial insulating material as described above with reference to FIGS. 19 to 20B. The second material layer 213 may be replaced by a third material layer which is described with reference to FIGS. 35A and 35B.

FIGS. 37A and 37B are diagrams illustrating another embodiment of a process of forming a trench and a process of forming an insulating partition wall.

Referring to FIG. 37A, a trench 361 may extend in the first direction DR1 to pass through a first dielectric layer 321 of the blocking insulating layer 220 and the preliminary stack structure 210 as well as the insulating pillar 235 and the channel layer 231 shown in FIGS. 31, 32A, and 32B. As a result, the first pillar pattern 235A, the second pillar pattern 235B, the first channel pattern 231A, the second pillar pattern 235B, the first channel pattern 231A, the second channel pattern 231B, the first tunnel insulating pattern 229A, and the second tunnel insulating pattern 229B may be defined by the trench 361. Further, the preliminary stack structure 210 shown in FIGS. 31, 32A, and 32B may also be separated into a first stacked pattern 210A and a second stacked pattern 210B. In addition, the first dielectric layer may be separated into a first pattern 221A and a second pattern 221B. As a result, the blocking insulating layer may be separated into a first blocking insulating pattern 220A and a second blocking insulating pattern 220B. The first blocking insulating pattern 220A may include the first patterns 221A, 223A2, and 225A of the first dielectric layer, the second dielectric layer, and the third dielectric layer. The second blocking insulating pattern 220B may include the second patterns 221B, 223B2, and 225B of the first dielectric layer, the second dielectric layer, and the third dielectric layer.

The first pillar pattern 235A, the first channel pattern 231A, and the first tunnel insulating pattern 229A may form a first vertical structure 230A. The second pillar pattern 235B, the second channel pattern 231B, and the second tunnel insulating pattern 229B may form a second vertical structure 230B.

Hereinafter, a plurality of second material layers of the first stacked pattern 210A may be referred to as a first group of second material layers 213A, and a plurality of second material layers of the second stacked pattern 210B may be referred to as a second group of second material layers 213B. The second material layer 213A in the first group the may be separated from the second material layer 213B in the second group by the trench 361.

Referring to FIG. 37B, the trench 361 shown in FIG. 37A may be filled with an insulating material. As a result, an insulating partition wall 245 may be formed in the trench 361 shown in FIG. 37A.

After the insulating partition wall 245 is formed, the slit SI of FIG. 4 may be formed through each of the first stacked pattern 210A and the second stacked pattern 210B. The second material layer 213A of the first group and the second material layer 213B of the second group as shown in FIGS. 37A and 37B may include a sacrificial insulating material in the same manner as the second material layer as described above with reference to FIG. FIGS. 19 to 20B. Each of the second material layer 213A of the first group and the second material layer 213B of the second group may be replaced by the third material layer as described above with reference to FIGS. 35A and 35B.

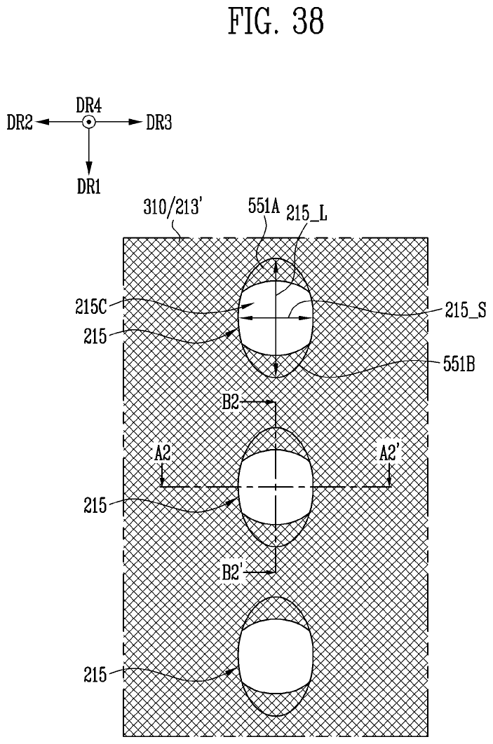

FIGS. 38, 39A, 39B, 40, 41A, 41B, and 42 are diagrams illustrating a method of manufacturing a semiconductor memory device according to an embodiment of the present disclosure.

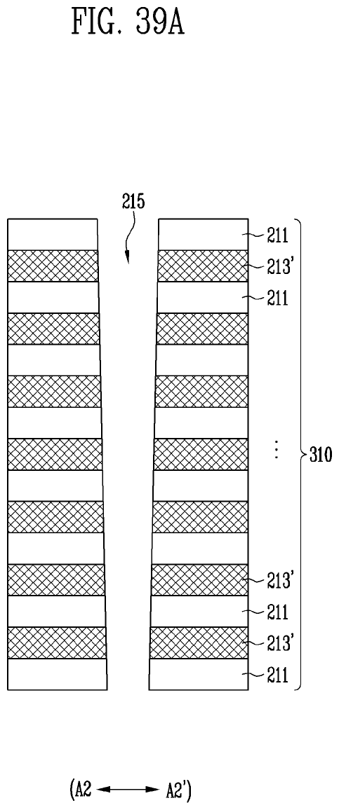

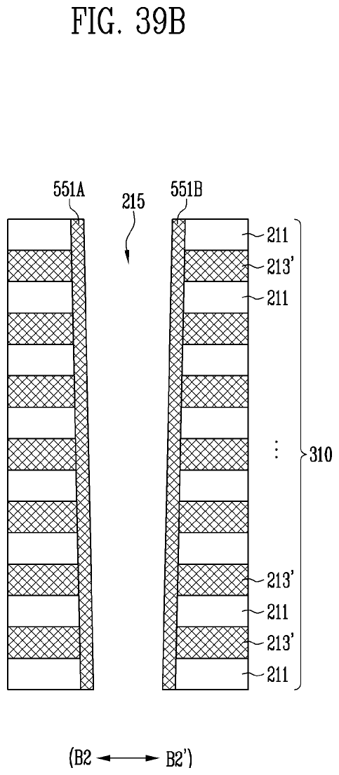

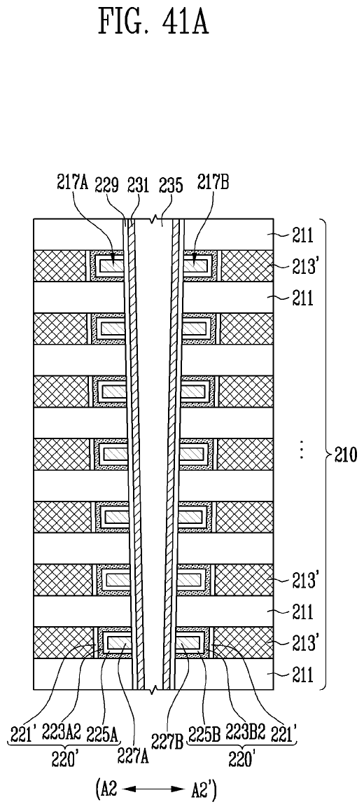

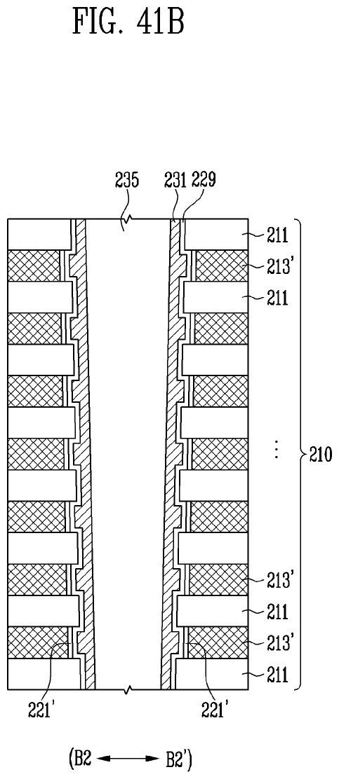

FIGS. 38, 40, and 42 are plan views illustrating processes. FIGS. 39A and 41A are cross-sectional diagrams taken along line A2-A2′ of plan views corresponding thereto for illustrating processes. FIGS. 39B and 41B are cross-sectional diagrams taken along line B2-B2′ of plan views corresponding thereto for illustrating processes. Hereinafter, a description of the same processes as described in FIGS. 19 to 35B will be simplified or omitted.

FIGS. 38, 39A, and 39B are diagrams illustrating processes of forming a preliminary stack structure 310 penetrated by the plurality of holes 215 and processes of forming a first etch barrier pattern 551A and a second etch barrier pattern 551B.

Referring to FIGS. 38, 39A, and 39B, the preliminary stack structure 310 may be formed on the lower structure (not shown) as described above with reference to FIGS. 19 to 20B. The preliminary stack structure 310 may be penetrated by the plurality of holes 215. As described above with reference to FIGS. 19 to 20B, a cross-section of each hole 215 may include the major axis 215_L in the first direction DR1 and the minor axis 215_S in the third direction DR3.

The preliminary stack structure 310 may include the plurality of first material layers 211 and a plurality of second material layers 213′ that are stacked alternately with each other in the fourth direction DR4. The plurality of first material layers 211 may include an insulating material such as a silicon oxide layer. The plurality of second material layers 213′ may include the same conductive material as the third material layer as described above with reference to FIGS. 35A and 35B.

The hole 215 may be formed in the preliminary stack structure 310 by using the processes as described with reference to FIGS. 19 to 20B.

Subsequently, the first etch barrier pattern 551A and the second etch barrier pattern 551B may be formed to partially block a side portion of each of the plurality of first material layers 211 and the plurality of second material layers 213′ which are exposed through the hole 215. The first etch barrier pattern 551A and the second etch barrier pattern 551B may include substantially the same material as the plurality of second material layers 213′. The first etch barrier pattern 551A and the second etch barrier pattern 551B may be separated from each other in the first direction DR1 to open the central area 215C of the hole 215. The first etch barrier pattern 551A and the second etch barrier pattern 551B may be formed to expose the inner walls of the hole 215 in the second direction DR2 and the third direction DR3. The first etch barrier pattern 551A and the second etch barrier pattern 551B may be formed using the processes described with reference to FIGS. 19 to 20B, and may have the same structure as described above with reference to FIGS. 19 to 20B.

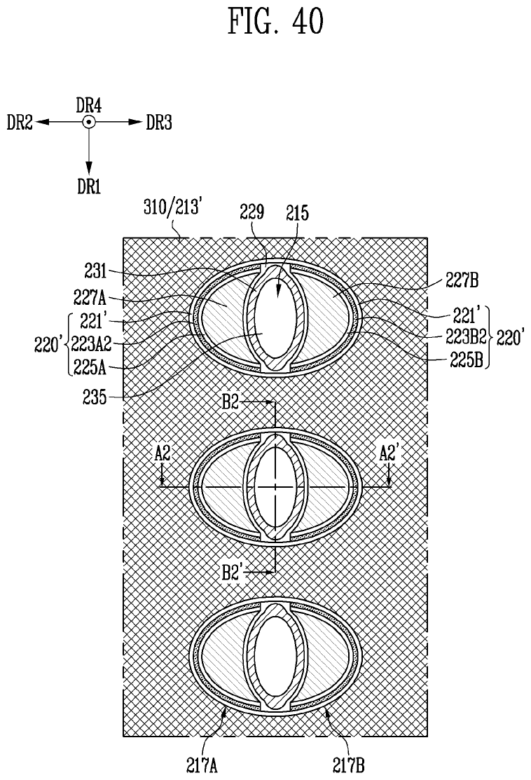

FIGS. 40, 41A, and 41B are diagrams illustrating processes of forming the first lateral groove 217A and the second lateral groove 217B, processes of forming a blocking insulating layer 220′, processes of forming the first data storage pattern 227A and the second data storage pattern 227B, and processes performed in the hole 215.

Referring to FIGS. 40, 41A, and 41B, the first etch barrier pattern 551A and the second etch barrier pattern 551B shown in FIGS. 38 and 39B may be removed at the same time as the first lateral groove 217A and the second lateral groove 217B are formed at the side portion of the preliminary stack structure 310 by using the processes described with reference to FIGS. 21, 22A, and 22B.

Subsequently, the side portion of each of the plurality of second material layers 213′ which are exposed through the hole 215 and the first lateral groove 217A and the second lateral groove 217B may be oxidized to form a first dielectric layer 221′. Subsequently, the processes of forming the second dielectric layer as described with reference to FIGS. 23 to 24B, the processes of separating the second dielectric layer into the first preliminary pattern and the second preliminary pattern as described above with reference to FIGS. 25 to 26B, and the processes of oxidizing the portion of the first preliminary pattern and the portion of the second preliminary pattern as described above with reference to FIGS. 27 and 28 may be performed. As a result, the first dielectric layer 221′, the first pattern 223A2 and the second pattern 223B2 of the second dielectric layer, and the first pattern 225A and the second pattern 225B of the third dielectric layer may form the blocking insulating layer 220′.

Subsequently, the first data storage pattern 227A and the second data storage pattern 227B may be formed in the same manner as described above with reference to FIGS. 29 and 30. Subsequently, in the same manner as described above with reference to FIGS. 31 to 32B, the tunnel insulating layer 229, the channel layer 231, and the insulating pillar 235 may be formed in the hole 215.

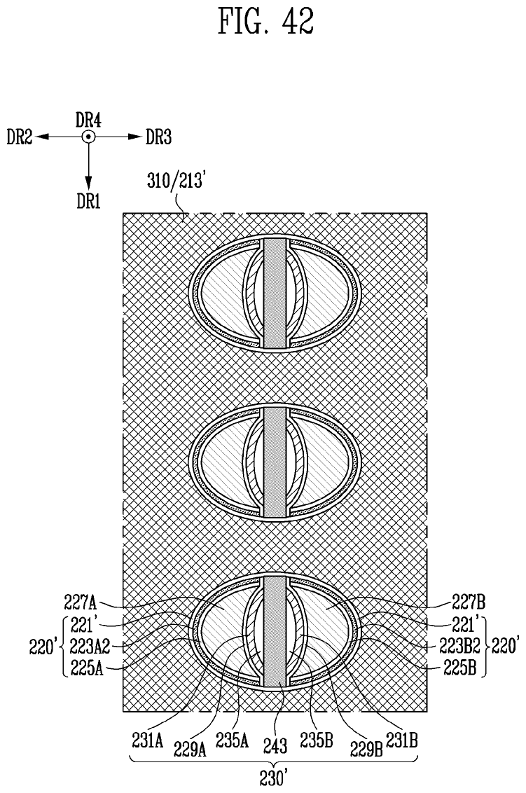

FIG. 42 is a plan view illustrating processes of separating the channel layer 231 into the first channel pattern 231A and the second channel pattern 231B.

Referring to FIG. 42, a trench may be formed through the channel layer 231 and the insulating pillar 235 as shown in FIG. 40 by using the processes described above with reference to FIG. 36A, and the insulating partition wall 243 may be formed in the trench by using the processes described above with reference to FIG. 36B. As a result, the vertical structure 230′ which includes the insulating partition wall 243, the first pillar pattern 235A, the second pillar pattern 235B, the first channel pattern 231A, the second channel pattern 231B, the first tunnel insulating pattern 229A, and the second tunnel insulating pattern 229B may be formed.

Subsequently, the preliminary stack structure 310 may be penetrated by the slit SI as described above with reference to FIG. 4. As a result, the preliminary stack structure 310 may be divided in units of gate stack structures. The second material layers 213′ of the preliminary stack structure 310 may serve as gate electrodes for controlling the first channel pattern 231A and the second channel pattern 231B.

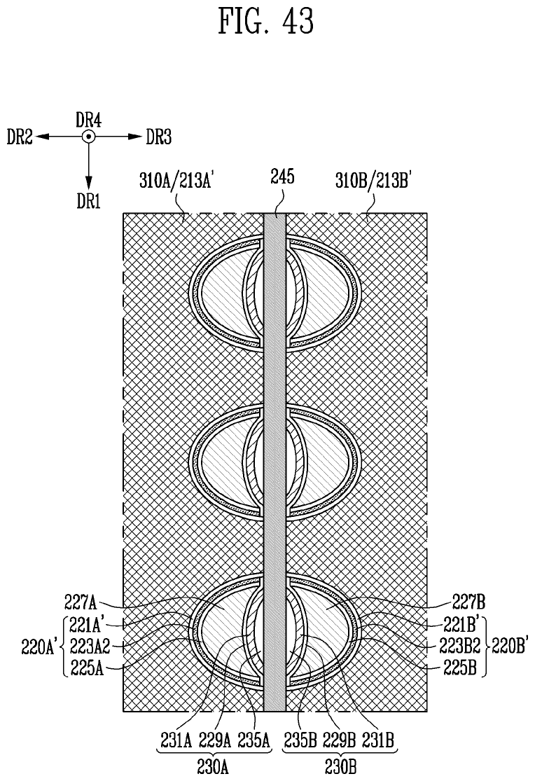

FIG. 43 is a plan view illustrating a method of manufacturing a semiconductor memory device according to an embodiment of the present disclosure.

FIG. 43 is a plan view illustrating another embodiment of processes of forming a trench and processes of forming an insulating partition wall. Before the processes shown in FIG. 43 are performed, the processes described with reference to FIGS. 38 to 41B may be performed.

Referring to FIG. 43, a trench may be formed through the channel layer 231 and the insulating pillar 235 as shown in FIG. 40 by using the processes described above with reference to FIG. 37A, and the insulating partition wall 245 may be formed in the trench by using the processes described above with reference to FIG. 37B. As a result, the first pillar pattern 235A, the second pillar pattern 235B, the first channel pattern 231A, the second channel pattern 231B, the first tunnel insulating pattern 229A, and the second tunnel insulating pattern 229B may be defined by the insulating partition wall 245. Further, the preliminary stack structure 310 shown in FIGS. 40 to 41B may be separated into a first stacked pattern 310A and a second stacked pattern 310B. In addition, the first dielectric layer may be separated into a first pattern 221A′ and a second pattern 221B′.

As described above, the blocking insulating layer may be separated into a first blocking insulating pattern 220A′ and a second blocking insulating pattern 220B′. The first blocking insulating pattern 220A′ may include the first patterns 221A′, 223A2, and 225A of the first dielectric layer, the second dielectric layer, and the third dielectric layer. The second blocking insulating pattern 220B′ may include the second patterns 221B′, 223B2, and 225B of the first dielectric layer, the second dielectric layer, and the third dielectric layer. In addition, the first pillar pattern 235A, the first channel pattern 231A, and the first tunnel insulating pattern 229A may form the first vertical structure 230A. The second pillar pattern 235B, the second channel pattern 231B, and the second tunnel insulating pattern 229B may form the second vertical structure 230B. In addition, the plurality of second material layers of the first stacked pattern 310A may remain as a plurality of first conductive patterns 213A′, and the plurality of second material layers of the second stacked pattern 310B may remain as a plurality of second material layers 213B′.

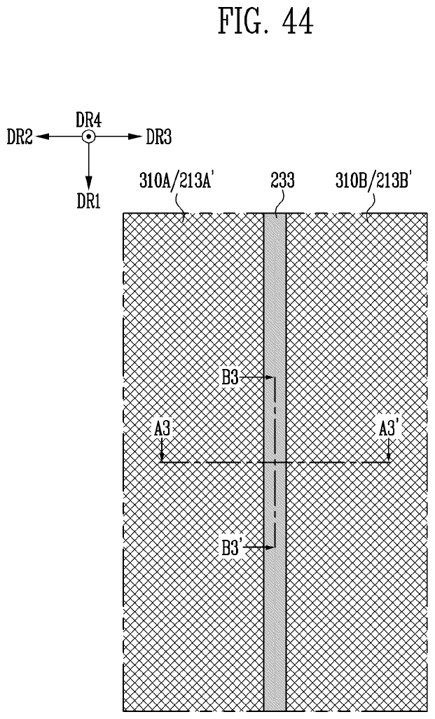

FIGS. 44, 45A, 45B, 46, 47A, 47B, 48, 49A and 49B are diagrams illustrating a method of manufacturing a semiconductor memory device according to an embodiment of the present disclosure.

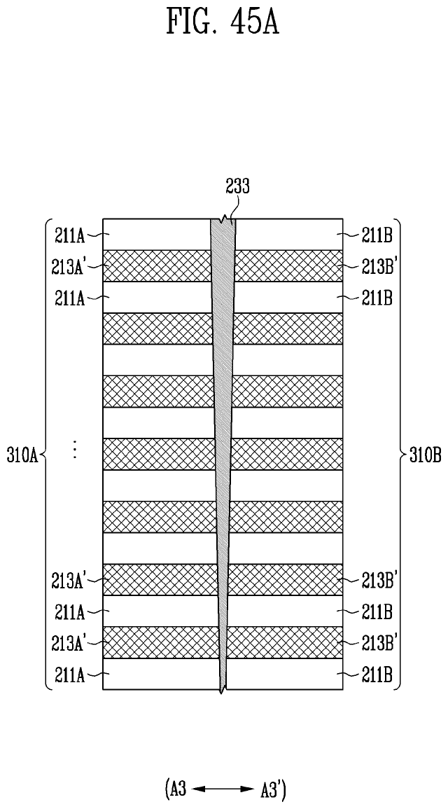

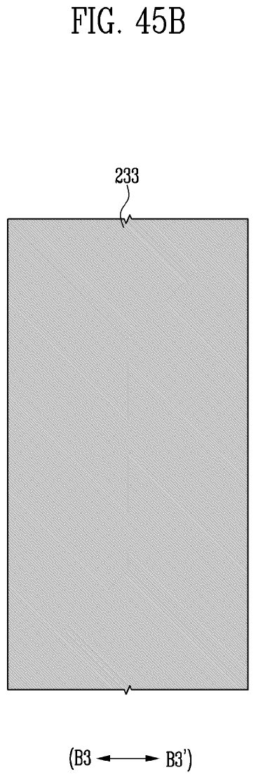

FIGS. 44, 46, and 48 are plan views illustrating processes. FIGS. 45A, 47A, and 49A are cross-sectional diagrams taken along line A3-A3′ of plan views corresponding thereto for illustrating processes. FIGS. 45B, 47B, and 49B are cross-sectional diagrams taken along line B3-B3′ of plan views corresponding thereto for illustrating processes. Hereinafter, a description of the same processes as described in FIGS. 19 to 35B will be simplified or omitted.

FIGS. 44, 45A, and 45B are diagrams illustrating processes of forming a first insulating partition wall 233.

Referring to FIGS. 44, 45A, and 45B, a preliminary stack structure may be formed by alternately stacking a plurality of first material layers and a plurality of second material layers on a lower structure (not shown) as described above with reference to FIGS. 44, 45A, and 45B. The plurality of first material layers may include an insulating material such as a silicon oxide layer. The plurality of second material layers may include the same conductive material as the third material layer as described above with reference to FIGS. 35A and 35B.

Subsequently, the first insulating partition wall 233 may be formed through the preliminary stack structure. The first insulating partition wall 233 may extend in the first direction DR1 and separate the preliminary stack structure into a first stacked pattern 310A and a second stacked pattern 310B. A plurality of first material layers of the first stacked pattern 310A may remain as a plurality of interlayer insulating patterns 211A. A plurality of second material layers may remain as the plurality of first conductive patterns 213A′. A plurality of first material layers of the second stacked pattern 310B may remain as a plurality of interlayer insulating patterns 211B. The plurality of second material layers may remain as a plurality of second conductive patterns 213B′.

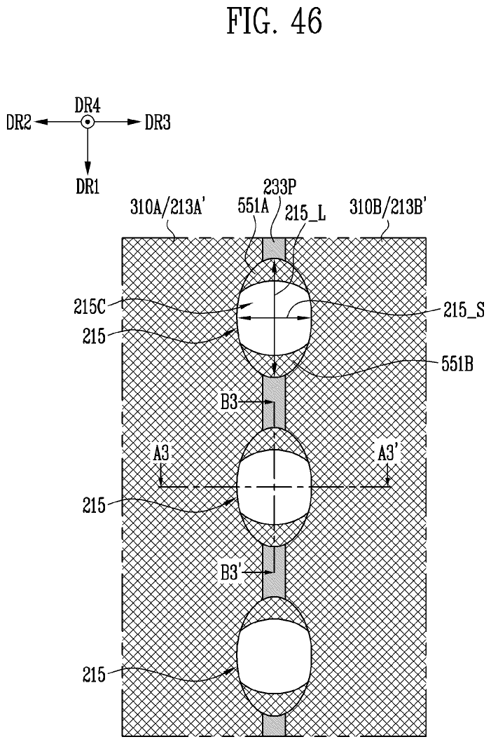

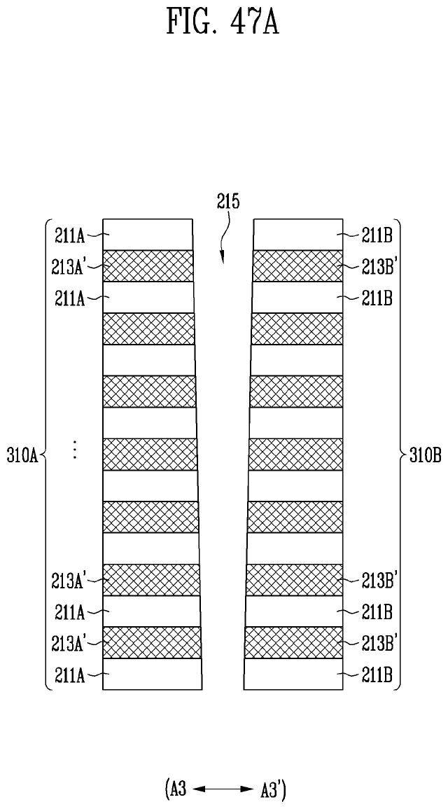

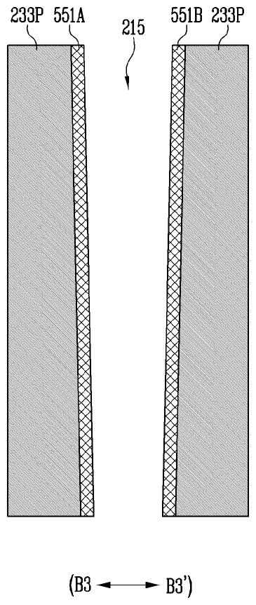

FIGS. 46, 47A, and 47B are diagrams illustrating processes of forming the plurality of holes 215 and processes of forming the first etch barrier pattern 551A and the second etch barrier pattern 551B.

Referring to FIGS. 46, 47A, and 47B, the plurality of holes 215 may be formed through a portion of the first insulating partition wall 233 as shown in FIGS. 44 and 45B. As described above with reference to FIGS. 19 to 20B, a cross-section of each hole 215 may include the major axis 215_L in the first direction DR1 and the minor axis 215_S in the third direction DR3. The major axis 215_L of the hole 215 may overlap the first insulating partition wall 233 as shown in FIGS. 44 and 45B. Hereinafter, another portion of the first insulating partition wall which does not overlap the hole 215 and is not penetrated by the hole 215 is denoted by “233P.”

One side of the hole 215 may extend convexly in the second direction DR2 to pass through a portion of each of the plurality of first interlayer insulating patterns 211A and the plurality of first conductive patterns 213A′ of the first stacked pattern 310A and may extend in the fourth direction DR4. Another side of the hole 215 may extend convexly in the third direction DR3 to pass through a portion of each of the plurality of second interlayer insulating patterns 211B and the plurality of second conductive patterns 213B′ of the second stacked pattern 310B and may extend in the fourth direction DR4.

Subsequently, the first etch barrier pattern 551A and the second etch barrier pattern 551B may be formed. The first etch barrier pattern 551A and the second etch barrier pattern 551B may include substantially the same material as the plurality of first conductive patterns 213A′ and the plurality of second conductive patterns 213B′. The first etch barrier pattern 551A and the second etch barrier pattern 551B may be separated in the first direction DR1 to open the central area 215C of the hole 215. The side portion of the first insulating partition wall 233P may be blocked by the first etch barrier pattern 551A and the second etch barrier pattern 551B. The first etch barrier pattern 551A and the second etch barrier pattern 551B may be formed using the processes described with reference to FIGS. 19 to 20B, and may have the same structure as described above with reference to FIGS. 19 to 20B.

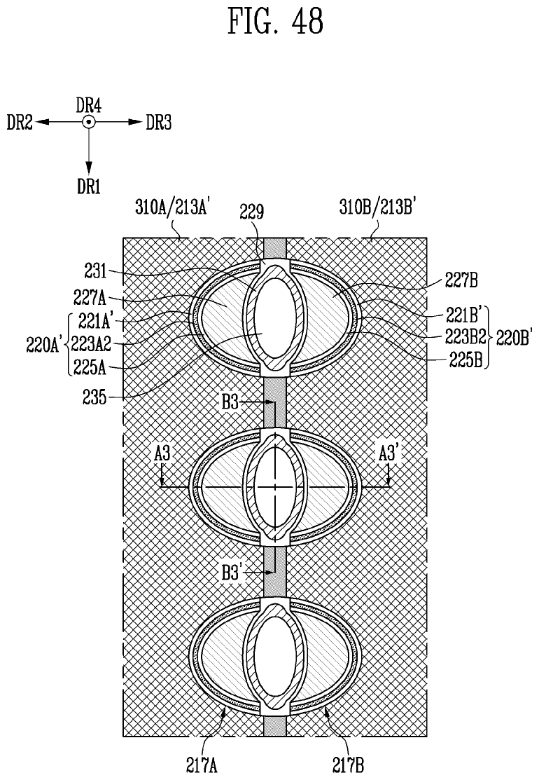

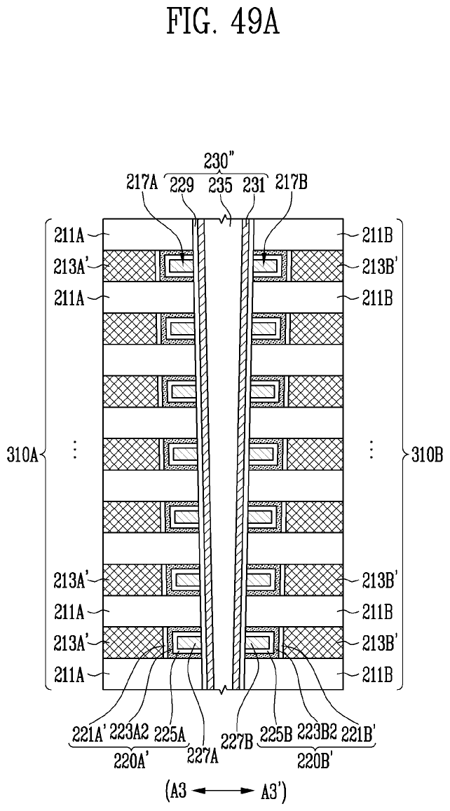

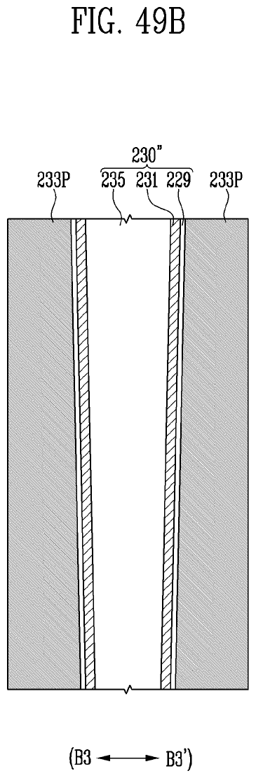

FIGS. 48, 49A, and 49B are diagrams illustrating processes of forming the first lateral groove 217A and the second lateral groove 217B, processes of forming the blocking insulating layer 220′, processes of forming the first data storage pattern 227A and the second data storage pattern 227B, and processes performed in the hole 215 as shown in FIG. 46.

Referring to FIGS. 48, 49A, and 49B, the first etch barrier pattern 551A and the second etch barrier pattern 551B shown in FIGS. 46 and 47B may be removed at the same time as the first lateral groove 217A is formed at the side portion of the first stacked pattern 310A and the second lateral groove 217B is formed at the side portion of the second stacked pattern 310B by using the processes described with reference to FIGS. 21, 22A, and 22B.

Subsequently, the first pattern 221A′ and the second pattern 221B′ of the first dielectric layer may be formed by oxidizing the side portion of each of the plurality of first conductive patterns 213A′ and the plurality of second conductive patterns 213B′ exposed through the hole 215 and the first and second lateral grooves 217A and 217B. Subsequently, the processes of forming the second dielectric layer as described with reference to FIGS. 23 to 24B, the processes of separating the second dielectric layer into the first preliminary pattern and the second preliminary pattern as described above with reference to FIGS. 25 to 26B, and the processes of oxidizing the portion of the first preliminary pattern and the portion of the second preliminary pattern as described above with reference to FIGS. 23 to 24B may be performed. As a result, the first pattern 223A2 and the second pattern 223B2 of the second dielectric layer and the first pattern 225A and the second pattern 225B of the third dielectric layer may be formed. The first patterns ‘21A’, 223A2, and 225A of the first to third dielectric layers may be disposed in the first lateral groove 217A and form the first blocking insulating pattern 220A′. The second patterns ‘21B’, 223B2, and 225B of the first, second, and third dielectric layers may be disposed in the second lateral groove 217B and form the second blocking insulating pattern 220B′.

Subsequently, the first data storage pattern 227A and the second data storage pattern 227B may be formed in the same manner as described above with reference to FIGS. 29 and 30. Subsequently, in the same manner as described above with reference to FIGS. 31 to 32B, the tunnel insulating layer 229, the channel layer 231, and the insulating pillar 235 may be formed in the hole 215. The tunnel insulating layer 229, the channel layer 231 and the insulating pillar 235 may form a vertical structure 230″.

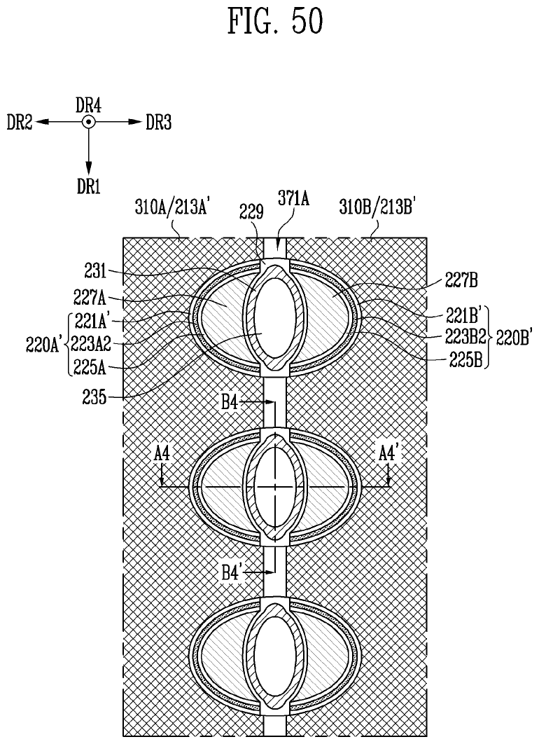

FIGS. 50, 51, 52, 53, 54, 55, 56 and 57 are diagrams illustrating a method of manufacturing a semiconductor memory device according to an embodiment of the present disclosure.

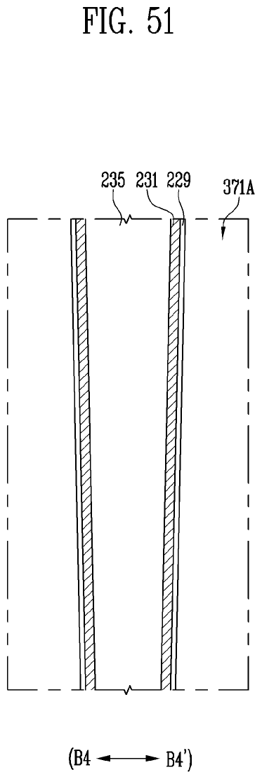

FIGS. 50, 52, 54, and 56 are plan views illustrating processes. FIGS. 51, 53, 55, and 57 are cross-sectional diagrams taken along line B4-B4′ of plan views corresponding thereto for illustrating processes. Cross-sectional diagrams taken along line A4-A4′ of FIGS. 50, 52, 54, and 56, respectively, are not provided since they are the same as FIG. 35A.

Before the processes of FIGS. 50 to 57 are performed, the processes as described above with reference to FIGS. 44 to 49B may be performed. FIGS. 50 to 57 are diagrams illustrating processes of separating the channel layer 231 shown in FIGS. 48, 49A, and 49B into a first channel pattern and a second channel pattern.

Referring to FIGS. 50 and 51, a first recessed portion 371A may be formed by removing the first insulating partition wall 233P shown in FIGS. 48 and 49B. The tunnel insulating layer 229 may be exposed by the first recessed portion 371A.

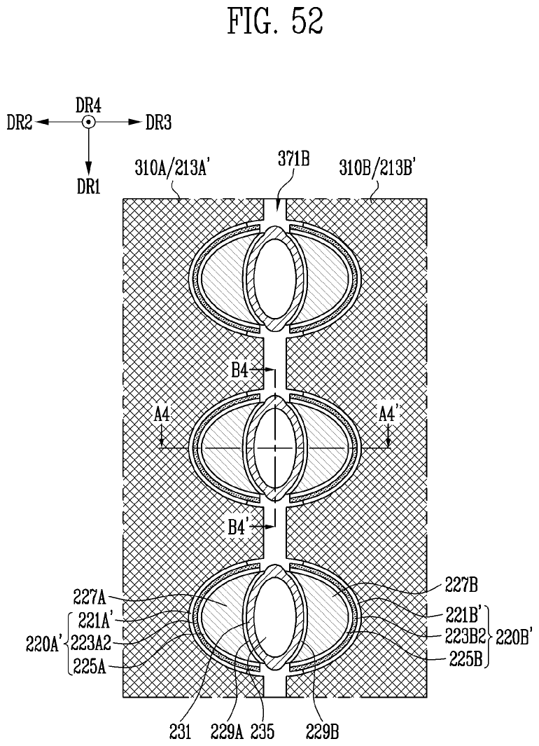

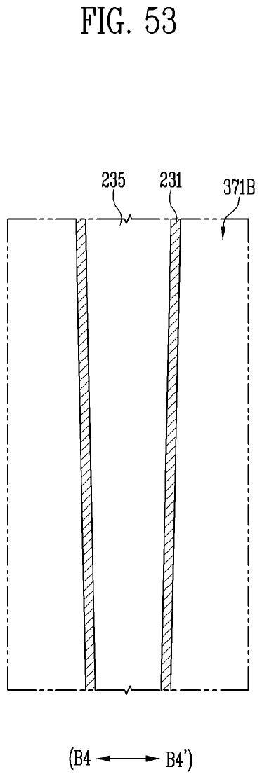

Referring to FIGS. 52 and 53, the first recessed portion may be extended by removing a portion of the tunnel insulating layer exposed through the first recessed portion 371A shown in FIGS. 50 and 51. Hereinafter, the extended first recessed portion is referred to as a second recessed portion 371B. The tunnel insulating layer may be separated into the first tunnel insulating pattern 229A and the second tunnel insulating pattern 229B by the second recessed portion 371B. The channel layer 231 may be exposed by the second recessed portion 371B.

Due to the influence of the etch process of removing the portion of the tunnel insulating layer, a portion of the first pattern 221A′ of the first dielectric layer may be etched from the first blocking insulating pattern 220A′ and a portion of the second pattern 221B′ of the first dielectric layer may be etched from the second blocking insulating pattern 220B′. As a result, the first pattern 223A2 of the second dielectric layer and the second pattern 223B2 of the second dielectric layer may remain protruding from the first blocking insulating pattern 220A′ and the second blocking insulating pattern 220B′ more than the first and second patterns 221A′ and 221B′ of the first dielectric layer toward the second recessed portion 371B.

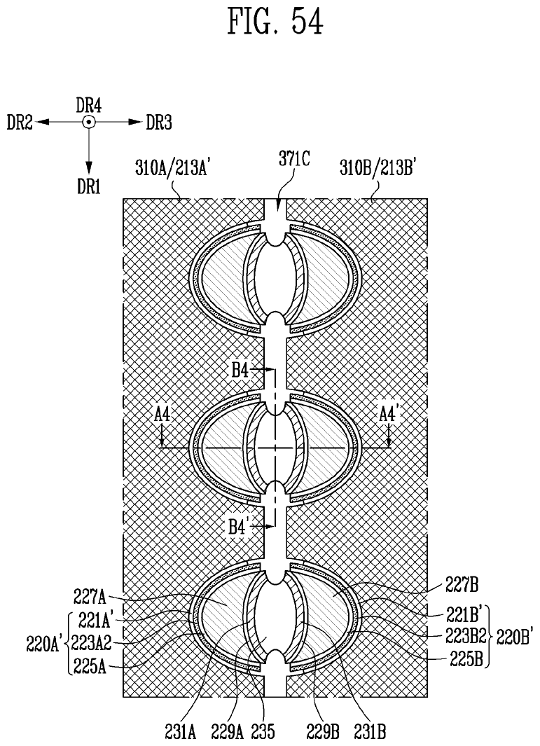

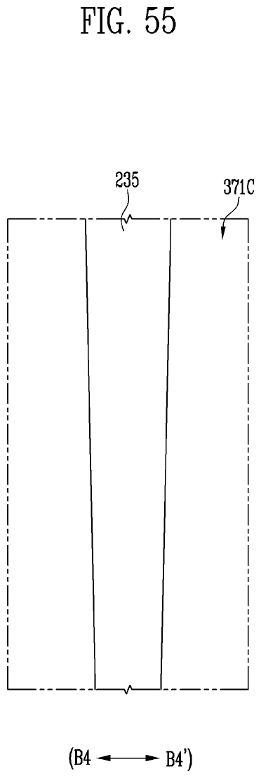

Referring to FIGS. 54 and 55, by removing a portion of the channel layer exposed through the second recessed portion 371B shown in FIGS. 52 and 53, the second recessed portion may be extended. Hereinafter, the extended second recessed portion is referred to as a third recessed portion 371C. The channel layer may be separated into the first channel pattern 231A and the second channel pattern 231B by the third recessed portion 371C. The insulating pillar 235 may be exposed by the third recessed portion 371C.

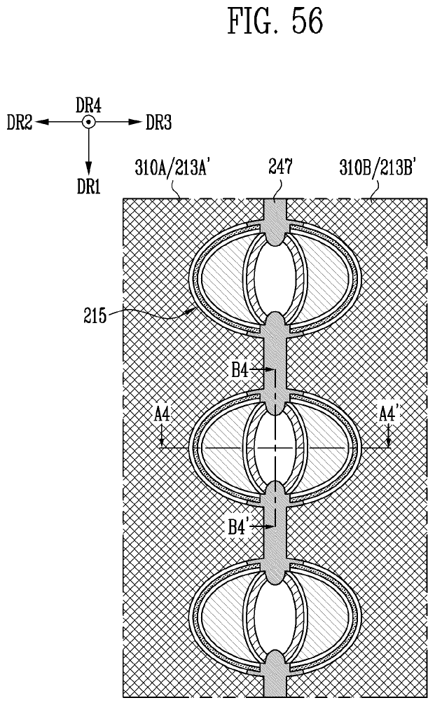

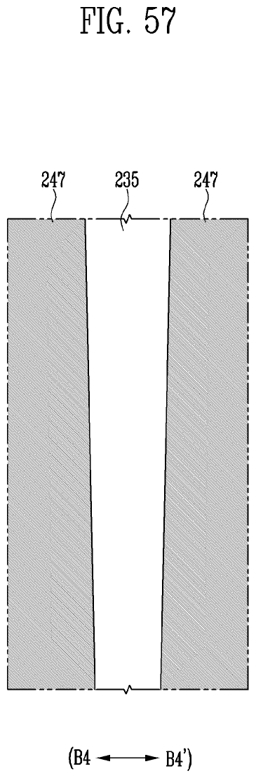

Referring to FIGS. 56 and 57, a second insulating partition wall 247 may be formed by filling the third recessed portion 371C shown in FIGS. 54 and 55 with an insulating material.

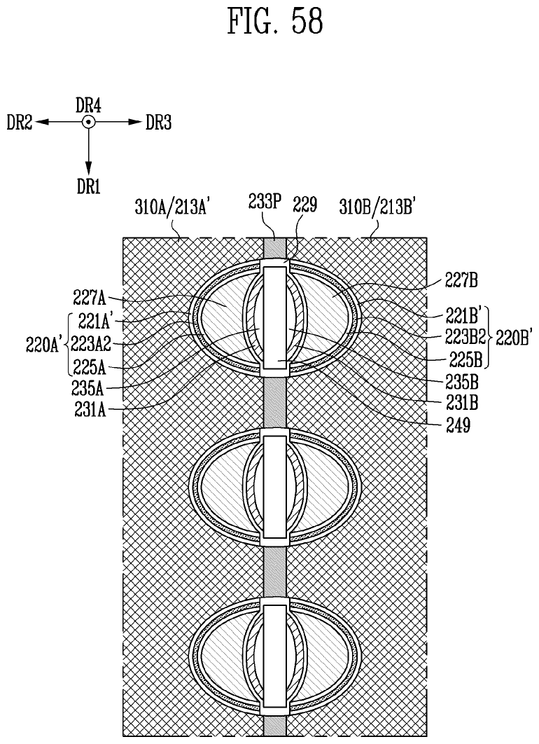

FIG. 58 is a plan view illustrating a method of manufacturing a semiconductor memory device according to an embodiment of the present disclosure.

Before processes shown in FIG. 58 are performed, the processes as described above with reference to FIGS. 44 to 49B may be performed. FIG. 58 is a diagram illustrating another embodiment of separating the channel layer 231 shown in FIGS. 48, 49A, and 49B into a first channel pattern and a second channel pattern.

Referring to FIG. 58, a trench may be formed. The trench may extend from the center of the insulating pillar 235 shown in FIGS. 48 to 49B toward the first insulating partition wall 233P to pass through the channel layer 231. According to an embodiment, the trench may be separated from the first insulating partition wall 233P and formed in the tunnel insulating layer 229. According to another embodiment, the trench may extend in the first direction DR1 to pass through the tunnel insulating layer 229 to expose the first insulating partition wall 233P.

Subsequently, a second insulating partition wall 249 may be formed by filling the trench with an insulating material. The insulating pillar may be separated into the first pillar pattern 235A and the second pillar pattern 235B by the trench and the second insulating partition wall 249 therein. The channel layer may be separated into the first channel pattern 231A and the second channel pattern 231B.

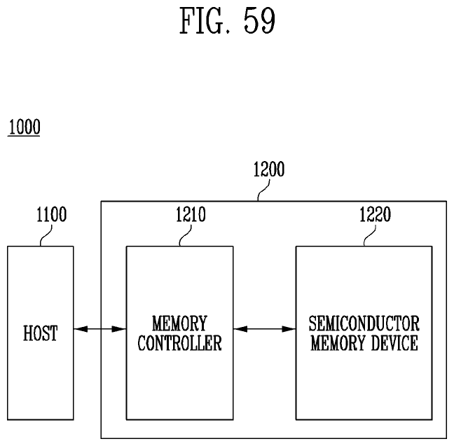

FIG. 59 is a block diagram illustrating an electronic system 1000 including a semiconductor memory device according to embodiments of the present disclosure.

Referring to FIG. 59, the electronic system 1000 may include a computing system, a medical device, a communication device, a wearable device, or a memory system. The electronic system 1000 may include a host and a storage device 1200.

The host 1100 may store data in the storage device 1200, or may read the stored data from the storage device 1200 on the basis of an interface. The interface may include at least one of a Double Data Rate (DDR) interface, a Universal Serial Bus (USB) interface, a multimedia card (MMC) interface, an embedded MMC (eMMC) interface, a peripheral component interconnection (PCI) interface, a PCI-express (PCI-E) interface, an Advanced Technology Attachment (ATA) interface, a Serial-ATA interface, a Parallel-ATA interface, a small computer system interface (SCSI), an enhanced small disk interface (ESDI), an Integrated Drive Electronics interface (IDE), a Firewire interface, a Universal Flash Storage (UFS) interface, and a Nonvolatile Memory express (NVMe) interface.

The storage device 1200 may include a memory controller 1210 and a semiconductor memory device 1220. According to an embodiment, the storage device 1200 may be a storage medium such as a solid state drive (SSD), a universal serial bus (USB) memory, or the like.

The memory controller 1210 may store data in the semiconductor memory device 1220, or may read data stored in the semiconductor memory device 1220 in response to control of the host 1100.

The semiconductor memory device 1220 may include a single memory chip or a plurality of memory chips. The semiconductor memory device 1220 may store data or output stored data in response to control of the memory controller 1210.

The semiconductor memory device 1220 may be a nonvolatile memory device. The semiconductor memory device 1220 may include a lower interlayer insulating layer, an upper interlayer insulating layer, a channel pattern passing through the lower interlayer insulating layer and the upper interlayer insulating layer, a conductive layer facing the channel pattern between the lower interlayer insulating layer and the upper interlayer insulating layer, and a storage pattern arranged in a lateral groove, the lateral groove defined between the conductive layer and the channel pattern by the lower interlayer insulating layer and the upper interlayer insulating layer protruding toward the channel pattern more than the conducive layer. A distance from the conductive layer from the channel pattern may decrease toward an end of the lateral groove.

According to embodiments of the present disclosure, a lateral groove may be separated in a vertical direction by an interlayer insulating layer or an interlayer insulating pattern, and a width of the lateral groove may decrease to an end thereof in a plane. Accordingly, in an embodiment, charges stored in a data storage pattern disposed in the lateral groove may be prevented or mitigated from moving into another data storage pattern adjacent thereto in a vertical direction. In addition, in an embodiment, a reduction in electric field at an end of the data storage pattern may be prevented or mitigated. Accordingly, in an embodiment, operational reliability of the semiconductor memory device may be improved.

What is claimed is:

1. A semiconductor memory device, comprising:
a lower interlayer insulating layer overlapping a center line, the center line extending in a plane parallel to the lower interlayer insulating layer;
an upper interlayer insulating layer spaced apart from the lower interlayer insulating layer in a direction crossing the plane;
a first channel pattern and a second channel pattern extending to pass through the lower interlayer insulating layer and the upper interlayer insulating layer, the first channel pattern spaced apart from the second channel pattern, and the center line interposed between the first and second channel patterns;
a conductive layer arranged between the lower interlayer insulating layer and the upper interlayer insulating layer, the conductive layer including a first area facing the first channel pattern, a second area facing the second channel pattern, and a third area coupling the first area to the second area; and
a first data storage pattern formed in a first lateral groove, the first lateral groove defined between the conductive layer and the first channel pattern by the lower interlayer insulating layer and the upper interlayer insulating layer, the upper and lower insulating layers protruding toward the first channel pattern more than the conductive layer,
wherein a variable width of the first lateral groove in the plane decreases toward an end of the first lateral groove.

2. The semiconductor memory device of claim 1, further comprising a second data storage pattern formed in a second lateral groove, the second lateral groove defined between the conductive layer and the second channel pattern by the lower interlayer insulating layer and the upper interlayer insulating layer, the upper and lower insulating layers protruding toward the second channel pattern more than the conductive layer, and
wherein a variable width of the second lateral groove in the plane decreases toward an end of the second lateral groove.

3. The semiconductor memory device of claim 2,
wherein a width of the first data storage pattern decreases with decreasing distance of the first data storage pattern from the center line, and
wherein a width of the second data storage pattern decreases with decreasing distance of the second data storage pattern from the center line.

4. The semiconductor memory device of claim 2, wherein the second lateral groove is substantially symmetrical to the first lateral groove with respect to the center line.

5. The semiconductor memory device of claim 1, wherein the first lateral groove has a substantially semi-elliptical shape.

6. The semiconductor memory device of claim 1, further comprising:
a tunnel insulating layer having substantially a tubular shape and extending to surround an outer wall of the first channel pattern toward the first area of the conductive layer and an outer wall of the second channel pattern toward the second area of the conductive layer;
a semiconductor oxide layer overlapping the center line and arranged between an end of the first channel pattern and an end of the second channel pattern; and
an insulating pillar located at a central area of the tunnel insulating layer including the substantially tubular shape; and
a blocking insulating layer extending along a side portion of each of the first area and the second area of the conductive layer.

7. The semiconductor memory device of claim 1, further comprising:
an insulating partition wall interposed between the first channel pattern and the second channel pattern and overlapping the center line;
a pillar pattern arranged between the insulating partition wall and each of the first channel pattern and the second channel pattern;
a blocking insulating layer extending along a side portion of each of the first area and the second area of the conductive layer; and
a tunnel insulating layer extending along an outer wall of each of the first channel pattern and the second channel pattern toward the conductive layer.

8. A semiconductor memory device, comprising:
a first lower interlayer insulating pattern and a second lower interlayer insulating pattern spaced apart from each other with a center line interposed therebetween, the center line extending in a direction in a plane parallel to the each of the first and second lower interlayer insulating patterns;
a first upper interlayer insulating pattern spaced apart from the first lower interlayer insulating pattern in a direction crossing the plane;
a second upper interlayer insulating pattern spaced apart from the second lower interlayer insulating pattern in the direction crossing the plane;
a first channel pattern and a second channel pattern extending to pass from between the first lower interlayer insulating pattern and the second lower interlayer insulating pattern to between the first upper interlayer insulating pattern and the second upper interlayer insulating pattern, the first channel pattern and the second channel pattern spaced apart from each other with the center line interposed therebetween;
a first conductive pattern arranged between the first lower interlayer insulating pattern and the first upper interlayer insulating pattern;
a second conductive pattern arranged between the second lower interlayer insulating pattern and the second upper interlayer insulating pattern; and
a first data storage pattern formed in a first lateral groove, the first lateral groove defined between the first conductive pattern and the first channel pattern by the first lower interlayer insulating pattern and the first upper interlayer insulating pattern, the first lower interlayer insulating pattern and the first upper interlayer insulating pattern each protruding toward the first channel pattern more than the first conductive pattern,
wherein a variable width of the first lateral groove in the plane decreases toward an end of the first lateral groove.

9. The semiconductor memory device of claim 8, further comprising:
a second data storage pattern formed in a second lateral groove, the second lateral groove defined between the second conductive pattern and the second channel pattern by the second lower interlayer insulating pattern and the second upper interlayer insulating pattern, the second lower and upper interlayer insulating patterns protruding toward the second channel pattern more than the second conductive pattern,
wherein a variable width of the second lateral groove in the plane decreases toward an end of the second lateral groove.

10. The semiconductor memory device of claim 9,
wherein a width of the first data storage pattern decreases with decreasing distance of the first data storage pattern from the center line, and
wherein a width of the second data storage pattern decreases with decreasing distance of the second data storage pattern from the center line.

11. The semiconductor memory device of claim 9, wherein the second lateral groove is substantially symmetrical to the first lateral groove with respect to the center line.

12. The semiconductor memory device of claim 8, wherein the first lateral groove has a substantially semi-elliptical shape.

13. The semiconductor memory device of claim 8, further comprising:
an insulating partition wall interposed between the first channel pattern and the second channel pattern and extending between the first conductive pattern and the second channel pattern;
a first tunnel insulating pattern surrounding an outer wall of the first channel pattern toward the first conductive pattern;
a second tunnel insulating pattern surrounding an outer wall of the second channel pattern toward the second conductive pattern;
a first blocking insulating pattern extending along an inner wall of the first conductive pattern toward the first channel pattern;
a second blocking insulating pattern extending along an inner wall of the second conductive pattern toward the second channel pattern; and
a pillar pattern arranged between each of the first channel pattern and the second channel pattern and the insulating partition wall.

14. The semiconductor memory device of claim 8, further comprising:
a first tunnel insulating pattern surrounding an outer wall of the first channel pattern toward the first conductive pattern;
a second tunnel insulating pattern surrounding an outer wall of the second channel pattern toward the second conductive pattern;
a first blocking insulating pattern extending along an inner wall of the first conductive pattern toward the first channel pattern;
a second blocking insulating pattern extending along an inner wall of the second conductive pattern toward the second channel pattern;
an insulating pillar extending toward an inner wall of the second channel pattern from an inner wall of the first channel pattern; and
an insulating partition wall extending from the insulating pillar to be interposed between an end of the first channel pattern and an end of the second channel pattern and between the first conductive pattern and the second channel pattern.

15. The semiconductor memory device of claim 8, further comprising:
a first insulating partition wall interposed between the first conductive pattern and the second conductive pattern;
a second insulating partition wall arranged alternately with the first insulating partition wall in the direction in which the center line extends and including a portion interposed between an end of the first channel pattern and an end of the second channel pattern;
a tunnel insulating layer surrounding an outer wall of the first channel pattern toward the first conductive pattern and an outer wall of the second channel pattern toward the second conductive pattern;
a blocking insulating layer extending along an inner wall of the first conductive pattern toward the first channel pattern and an inner wall of the second conductive pattern toward the second channel pattern; and
a pillar pattern between each of the first channel pattern and the second channel pattern and the second insulating partition wall.

16. The semiconductor memory device of claim 15, wherein the tunnel insulating layer extends between the first insulating partition wall and the second insulating partition wall.

17. The semiconductor memory device of claim 15, wherein the blocking insulating layer includes a portion extending between the first insulating partition wall and the second insulating partition wall.

18. A semiconductor memory device, comprising:
a first lower interlayer insulating pattern and a second lower interlayer insulating pattern spaced apart from each other with a center line interposed therebetween, the center line extending in a direction in a plane parallel to each of the first and second lower interlayer insulating patterns;
a first upper interlayer insulating pattern spaced apart from the first lower interlayer insulating pattern in a direction crossing the plane;
a second upper interlayer insulating pattern spaced apart from the second lower interlayer insulating pattern in the direction crossing the plane;
a channel layer extending to pass from between the first lower interlayer insulating pattern and the second lower interlayer insulating pattern to between the first upper interlayer insulating pattern and the second upper interlayer insulating pattern;
a first conductive pattern arranged between the first lower interlayer insulating pattern and the first upper interlayer insulating pattern;
a second conductive pattern arranged between the second lower interlayer insulating pattern and the second upper interlayer insulating pattern; and
a first data storage pattern formed in a first lateral groove, the first lateral groove defined between the first conductive pattern and the channel layer by the first lower interlayer insulating pattern and the first upper interlayer insulating pattern, the first lower interlayer insulating pattern and the first upper interlayer insulating pattern each protruding toward the channel layer more than the first conductive pattern,
wherein a variable width of the first lateral groove in the plane decreases toward an end of the first data storage pattern.

19. The semiconductor memory device of claim 18, further comprising:
a second data storage pattern formed in a second lateral groove, the second lateral groove defined between the second conductive pattern and the channel layer by the second lower interlayer insulating pattern and the second upper interlayer insulating pattern, the second lower and upper interlayer insulating patterns protruding toward the channel layer more than the second conductive pattern,
wherein a variable width of the second lateral groove in the plane decreases toward an end of the second data storage pattern.

20. The semiconductor memory device of claim 19,
wherein a width of the first data storage pattern decreases with decreasing distance of the first data storage pattern from the center line, and
wherein a width of the second data storage pattern decreases with decreasing distance of the second data storage pattern from the center line.

21. The semiconductor memory device of claim 19, wherein the second lateral groove is substantially symmetrical to the first lateral groove with respect to the center line.

22. The semiconductor memory device of claim 19, wherein the first lateral groove has a substantially semi-elliptical shape.

23. The semiconductor memory device of claim 19, further comprising:
an insulating pillar arranged at a central region of the channel layer;
an insulating partition wall interposed between the first conductive pattern and the second conductive pattern;
a tunnel insulating layer surrounding an outer wall of the channel layer; and
a blocking insulating layer extending along an inner wall of the first conductive pattern toward the channel layer and an inner wall of the second conductive pattern toward the channel layer.

24. The semiconductor memory device of claim 23, wherein the channel layer and the tunnel insulating layer extend between the insulating pillar and the insulating partition wall.

25. The semiconductor memory device of claim 23, wherein the blocking insulating layer includes a portion extending between the insulating pillar and the insulating partition wall.
